(19) United States
(12) Patent Application Publication
(10) Pub. No.: US 2012/0221912 A1
(43) Pub. Date: Aug. 30, 2012

(54) OPTICAL TRANSMISSION AND RECEPTION SYSTEM AND OPTICAL RECEPTION DEVICE

(75) Inventor: Tsugio TAKAHASHI, Minato-ku (JP)

(73) Assignee: NEC CORPORATION, Tokyo (JP)

(21) Appl. No.: 13/370,930

(22) Filed: Feb. 10, 2012

(30) Foreign Application Priority Data
Feb. 28, 2011 (JP) 2011-043152

(51) Int. Cl. H03M 13/05; G06F 11/10

(52) U.S. Cl. 714/752; 714/E11.032

(57) ABSTRACT

An object of the invention of the present patent application is to provide a frame synchronization technique that will not be prone to enter a frame asynchronization state even if a bit error occurs over a transmission path and the technique serves to convert a received optical signal into an electric signal, correct an error of the electric signal so as to cause a frame synchronization establishment state to occur, count the successive number of synchronization words that have bit errors in excess of an allowable value in an error-correction-coded electric signal after the frame synchronization establishment state has occurred, and determine that a frame asynchronization state has occurred when the successive number reaches a predetermined number.

The present application claims priority based on Japanese Patent Application JP 2011-043152 filed on Feb. 28, 2011, the entire contents of which are incorporated herein by reference in its entirety.

### BACKGROUND OF THE INVENTION

1. Field of the Invention

The present invention relates to a frame synchronization technique for an optical transmission and reception system and an optical reception device.

2. Description of Related Art

Currently, various attempts are being made in the field of optical transmission schemes so as to improve the reliability of transmission paths of communication lines. For example, a technique that uses two systems of frame synchronization circuits and switches over between an active line and a backup line without instantaneous interruption has been proposed (for example, refer to Patent Literature 1).

In addition, as digital circuit techniques have advanced, the FEC (Forward Error Correction) technique that has high error correction capability has been accomplished and implemented. By performing error corrections using such FEC technique, the reliability of transmission paths can be improved.

FIG. 1 is a schematic diagram showing an example of the structure of a communication frame used over a transmission line. FIG. 1 shows the structure of a frame applied to the current OTN (Optical Transport Network). In FIG. 1, one frame is composed of 16,320 bytes and the first six bytes are allocated as a synchronous word.

FIG. 2 is a schematic diagram showing the structure of an ordinary optical transmission and reception system that uses frames as shown in FIG. 1. In FIG. 2, reference numeral 70 represents an optical transmission device; reference numeral 71 represents a frame generation circuit; reference numeral 72 represents an FEC encoder; reference numeral 75 represents an electro-optical conversion circuit; reference numeral 40 represents an optical fiber transmission path; reference numeral 80 represents an optical reception device; reference numeral 85 represents an opto-electrical conversion circuit; reference numeral 82 represents an FEC decoder; reference numeral 81 represents a frame termination circuit; reference numeral 91 represents a synchronization word detection circuit; reference numeral 92 represents a frame synchronization detection circuit; reference numeral 93 represents a frame asynchronization detection circuit; and reference numeral 95 represents a receiver's frame synchronization indication circuit.

FIG. 3 is a schematic diagram showing a time chart that represents the operation of the optical transmission and reception system shown in FIG. 2. Synchronization word detection circuit 91 detects synchronization words from frames generated by frame generation circuit 71. In FIG. 2, when frame synchronization detection circuit 92 detects that synchronization words of frame numbers #3 and #4 do not have bit errors in succession, frame synchronization detection circuit 92 outputs a frame synchronization detection signal. When receiver's frame synchronization indication circuit 95 accepts the frame synchronization detection signal, receiver's frame synchronization indication circuit 95 causes a receiver's frame synchronization indication signal to go high and thereby the optical reception device enters a frame synchronization establishment state.

When the error rate of an optical fiber transmission path becomes high, the likelihood in which the synchronization words of OTN frames have errors becomes high. When frame asynchronization detection circuit 93 detects bit errors successively in synchronization words of frame numbers #n+1 to #n+7, frame asynchronization detection circuit 93 outputs a frame asynchronization detection signal. When receiver's frame synchronization indication circuit 95 accepts the frame asynchronization detection signal, receiver's frame synchronization indication circuit 95 causes the receiver's frame synchronization indication signal to go low. As a result, the optical reception device enters a frame asynchronization state.

### RELATED ART LITERATURE

### Patent Literature

Patent Literature 1: JP2003-124916A, Publication

### SUMMARY OF THE INVENTION

As FEC decoder 82 shown in FIG. 2 performs error correction, and although the error-corrected data signal does not have an error, but, there is some possibility that the receiver's frame synchronization indication circuit 95 may cause the receiver's frame synchronization signal to go low. In this case, the communication would shut down and a data signal would be lost until the frame synchronization establishment operation has been complete. Thus, if the error rate of the optical fiber transmission path is high, since it takes a time to cause the frame synchronization establishment state to occur, the amount of data that is lost would become large and thereby the throughput of the communication line would deteriorate.

Therefore, an object of the present invention is to provide a frame synchronization technique that would not be prone to enter the frame asynchronization state even if a bit error occurs over the transmission path.

To accomplish the foregoing object, according to the invention of the present patent application, after a received optical signal is converted into an electric signal, errors of the electric signal are corrected and after frame synchronization is established, the successive number of synchronization words that have bit errors in excess of an allowable value is counted and when the successive number reaches a predetermined number, it is determined that a frame asynchronization state has occurred.

The invention of the present patent application is an optical transmission and reception system, comprising: an optical transmission device including: a frame generation circuit that adds synchronization words to an input data signal so as to generate a framed electric signal; an FEC (Forward Error Correction) encoder that adds error correction code to said framed electric signal supplied from said frame generation circuit so as to generate an error-correction-coded electric signal, and an electro-optical conversion circuit that converts said error-correction-coded electric signal supplied from said FEC encoder into an optical signal and transmits the optical signal; and an optical reception device including: an opto-electric conversion circuit that accepts said optical signal from said electro-optical conversion circuit, converts the accepted optical signal into an electric signal, and reproduces said error-correction-coded electric signal; an earlier stage synchronization word detection circuit that detects said synchronization words from said error-correction-coded electric signal supplied from said opto-electric conversion circuit and outputs a frame-synchronized error-correction-coded electric signal; an earlier stage frame synchronization detection circuit that counts the successive number of said synchronization words in which no bit errors have been detected by said earlier stage synchronization word detection circuit, determines that a frame synchronization establishment state has occurred when the successive number reaches a predetermined number, and outputs a frame synchronization detection signal; an FEC decoder that corrects errors of said frame-synchronized error-correction-coded electric signal including said synchronization words supplied from said earlier stage synchronization word detection circuit and reproduces said framed electric signal; a later stage frame asynchronization detection circuit that counts the successive number of synchronization words that have bit errors in excess of an allowable value of said synchronization words contained in said framed electric signal supplied from said FEC decoder, determines that a frame asynchronization state has occurred when the successive number reaches a predetermined number, and outputs a later stage frame asynchronization detection signal; a receiver's frame synchronization indication output circuit that outputs a receiver's frame synchronization indication signal that causes the frame synchronization establishment state to occur based on said frame synchronization detection signal supplied from said earlier stage frame synchronization detection circuit and that causes the frame asynchronization state to occur based on said later stage frame asynchronization detection signal supplied from said later stage frame asynchronization detection circuit, and a frame termination circuit that removes said synchronization words from said framed electric signal supplied from said FEC decoder and reproduces said data signal.

The invention of the present patent application is an optical transmission and reception method, comprising: adding synchronization words to an input data signal so as to generate a framed electric signal; adding error correction code to said framed electric signal so as to generate an error-correction-coded electric signal; converting said error-correction-coded electric signal into an optical signal and transmitting the optical signal; receiving said optical signal, converting the received optical signal into an electric signal, and reproducing said error-correction-coded electric signal; detecting said synchronization words from said error-correction-coded electric signal and outputting a frame-synchronized error-correction-coded electric signal; counting the successive number of said synchronization words that do not have bit errors in said error-correction-coded electric signal, determining that a frame synchronization establishment state has occurred when the successive number reaches a predetermined number, and outputting a frame asynchronization detection signal; correcting errors of said frame-synchronized error-correction-coded electric signal including said synchronization words and reproducing said framed electric signal; counting the successive number of synchronization words that have bit errors in excess of an allowable value of said synchronization words contained in said framed electric signal, determining that a frame asynchronization state has occurred when the successive number reaches a predetermined number, and outputting a later stage frame asynchronization detection signal; and outputting a receiver's frame synchronization indication signal that causes the frame asynchronization state to occur based on said later stage frame asynchronization detection signal.

The invention of the present patent application is an optical reception device, comprising: an opto-electric conversion circuit that accepts an optical signal and converts the accepted optical signal into an electric signal so as to reproduce an error-correction-coded electric signal; an earlier stage synchronization word detection circuit that detects synchronization words from said error-correction-coded electric signal supplied from said opto-electric conversion circuit and outputs a frame-synchronized error-correction-coded electric signal; an earlier stage frame synchronization detection circuit counts the successive number of said synchronization words in which no bit errors have been detected by said earlier stage synchronization word detection circuit, determines that a frame synchronization establishment state has occurred when the successive number reaches a predetermined number, and outputs a frame synchronization detection signal; an FEC decoder that corrects errors of said frame-synchronized error-correction-coded electric signal including said synchronization words supplied from said earlier stage synchronization word detection circuit; a later stage frame asynchronization detection circuit that counts the successive number of synchronization words that have bit errors in excess of an allowable value of said synchronization words contained in said framed electric signal supplied from said FEC decoder, determines that a frame asynchronization state has occurred when the successive number reaches a predetermined number, and outputs a later stage frame asynchronization detection signal; a receiver's frame synchronization indication output circuit that outputs a receiver's frame synchronization indication signal that causes the frame synchronization establishment state to occur based on said frame synchronization detection signal supplied from said earlier stage frame synchronization detection circuit and that causes the frame asynchronization state to occur based on said later stage frame asynchronization detection signal supplied from said later stage frame asynchronization detection circuit; and a frame termination circuit that removes said synchronization words from said framed electric signal supplied from said FEC decoder and reproduces said data signal.

The invention of the present patent application is an optical reception method, comprising: receiving an optical signal and converting the received optical signal into an electric signal so as to reproduce an error-correction-coded electric signal; detecting said synchronization words from said error-correction-coded electric signal; outputting a frame-synchronized error-correction-coded electric signal; counting the successive number of said synchronization words in which no bit errors have been detected in said error correction coded electrical signal, determining that a frame synchronization establishment state has occurred when the successive number reaches a predetermined number, and outputting a frame synchronization detection signal; correcting errors of said frame-synchronized error-correction-coded electric signal including said synchronization words and reproducing said framed electric signal; counting the successive number of synchronization words that have bit errors in excess of an allowable value of said synchronization words contained in said framed electric signal, determining that a frame asynchronization state has occurred when the successive number reaches a predetermined number, and outputting a later stage frame asynchronization detection signal; and outputting a receiver's frame synchronization indication signal that causes the frame asynchronization state to occur based on said later stage frame asynchronization detection signal.

The invention of the present patent application is a computer readable record medium that records a program that causes a computer to execute procedures, comprising: an opto-electric conversion procedure that accepts an optical signal and converts the accepted optical signal into an electric signal so as to reproduce an error-correction-coded electric signal; an earlier stage synchronization word detection procedure that detects said synchronization words in said error-correction-coded electric signal and outputs a frame-synchronized error-correction-coded electric signal; an earlier stage frame synchronization detection procedure that counts the successive number of said synchronization words in which no bit errors have been detected by said earlier stage synchronization word detection procedure, determines that a frame synchronization establishment state has occurred when the successive number reaches a predetermined number, and outputs a frame synchronization detection signal; an FEC decode procedure that corrects errors of said frame-synchronized error-correction-coded electric signal including said synchronization words and reproduces said framed electric signal; a later stage frame asynchronization detection procedure that counts the successive number of synchronization words that have bit errors in excess of an allowable value of said synchronization words contained in said framed electric signal, determines that a frame asynchronization state has occurred when the successive number reaches a predetermined number, and outputs a later stage frame asynchronization detection signal; and a receiver's frame synchronization indication output procedure that outputs a receiver's frame synchronization indication signal that causes the frame asynchronization state to occur based on said later stage frame asynchronization detection signal.

According to the invention of the present patent application, a frame synchronization technique that would not be prone to enter a frame asynchronization state even if a bit error occurs over a transmission path can be provided.

### BRIEF DESCRIPTION OF THE DRAWINGS

FIG. 1 is a schematic diagram showing an example of the structure of a frame applied to the current OTN.

FIG. 2 is a schematic diagram showing an example of the structure of an ordinary optical transmission and reception system.

FIG. 3 is a schematic diagram showing the operation of an ordinary optical transmission and reception system.

FIG. 4 is a schematic diagram showing an example of the structure of an optical transmission and reception system according to embodiment 1 of the present invention.

FIG. 5 is a schematic diagram showing the operation of an optical reception device used for the optical transmission and reception system.

FIG. 6 is a schematic diagram showing an optical transmission and reception method according to embodiment 2.

FIG. 7 is a schematic diagram showing an example of the structure of an optical transmission and reception system according to embodiment 3.

FIG. 8 is a schematic diagram showing an example of the structure of an optical transmission and reception system according to embodiment 4.

FIG. 9 is a schematic diagram showing the structure of a selector used for the optical transmission and reception system.

FIG. 10 is a schematic diagram showing the structure of an OR circuit used for the optical transmission and reception system.

FIG. 11 is a schematic diagram showing the operation of an optical reception device according to embodiment 4.

FIG. 12 is a schematic diagram showing the operation of an optical reception device according to embodiment 5.

FIG. 13 is a schematic diagram showing the operation of an optical reception device according to embodiment 6.

FIG. 14 is a schematic diagram showing an example of an optical transmission and reception method according to embodiment 7.

FIG. 15 is a schematic diagram showing an example of the structure of an optical transmission and reception system according to embodiment 8.

FIG. 16 is a schematic diagram showing an example of procedures of an optical reception program according to embodiment 9.

FIG. 17 is a schematic diagram showing an example of procedures of an optical reception program according to embodiment 10.

FIG. 18 is a schematic diagram showing an example of the structure of an opto-electric conversion circuit used for an optical reception device.

### DETAILED DESCRIPTION OF THE PREFERRED EMBODIMENT

Next, with reference to the accompanying drawings, embodiments of the present invention will be described. The embodiments that will be described in the following are working examples of the present invention. Thus, the present invention is not limited to the embodiments that follow. Constituent sections with same reference numerals in this specification and drawings represent those that are identical.

### Embodiment 1

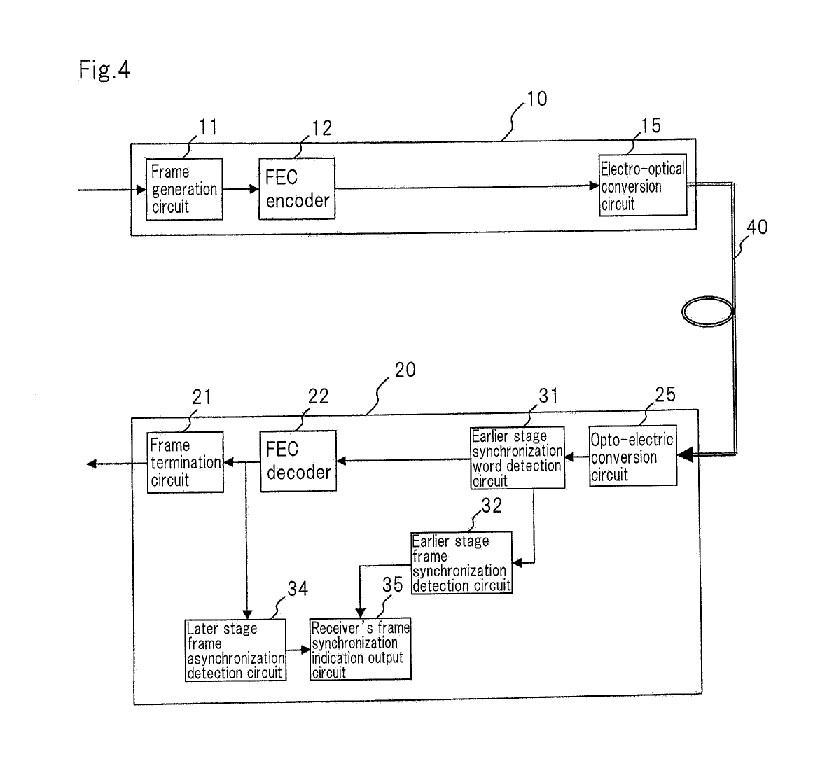

FIG. 4 is a schematic diagram showing an example of the structure of an optical transmission and reception system according to embodiment 1 of the present invention. In FIG. 4, the optical transmission and reception system has optical transmission device 10 and optical reception device 20 and they are connected by optical fiber transmission path 40. An optical repeater or the like may be connected in the middle of optical fiber transmission path 40.

Optical transmission device 10 is provided with frame generation circuit 11, FEC (Forward Error Correction) encoder 12, and electro-optical conversion circuit 15.

Frame generation circuit 11 adds synchronization words to an input data signal so as to generate a framed electric signal.

FEC encoder 12 adds error correction code to the framed electric signal supplied from frame generation circuit 11 so as to generate an error-correction-coded electric signal.

Electro-optical conversion circuit 15 converts the error-correction-coded electric signal supplied from FEC encoder 12 into an optical signal and transmits the converted optical signal.

Optical reception device 20 is provided with opto-electric conversion circuit 25, earlier stage synchronization word detection circuit 31, earlier stage frame synchronization detection circuit 32, FEC decoder 22, later stage frame asynchronization detection circuit 34, receiver's frame synchronization indication output circuit 35, and frame termination circuit 21.

Opto-electric conversion circuit 25 accepts the optical signal from electro-optical conversion circuit 15, converts the accepted optical signal into an electric signal, and then reproduces the error-correction-coded electric signal. Opto-electric conversion circuit 25 outputs the error-correction-coded electric signal to earlier stage synchronization word detection circuit 31.

When earlier stage synchronization word detection circuit 31 accepts the error-correction-coded electric signal from opto-electric conversion circuit 25, earlier stage synchronization word detection circuit 31 detects synchronization words contained in the error-correction-coded electric signal and outputs a frame-synchronized error-correction-coded electric signal to FEC decoder 22 and earlier stage frame synchronization detection circuit 32.

Earlier stage frame synchronization detection circuit 32 counts the successive number of synchronization words in which no bit errors have been detected by earlier stage synchronization word detection circuit 31. The successive number of synchronization words that do not have bit errors is the number of synchronization words that do not have bit errors and that are successively detected. When the successive number of synchronization words that have been counted reaches a predetermined number, earlier stage frame synchronization detection circuit 32 determines that a frame synchronization state of the data signal has occurred and outputs a frame synchronization detection signal to receiver's frame synchronization indication output circuit 35. Earlier stage frame synchronization detection circuit 32 has stored the predetermined number based on which it determines that the frame synchronization establishment state has occurred.

FEC decoder 22 corrects errors of the frame-synchronized error-correction-coded electric signal including the synchronization words supplied from earlier stage synchronization word detection circuit 31 and reproduces the framed electric signal. FEC decoder 22 outputs the reproduced framed electric signal to frame termination circuit 21 and later stage frame asynchronization detection circuit 34.

Later stage frame asynchronization detection circuit 34 counts the successive number of synchronization words that have bit errors in excess of an allowable value of the synchronization words contained in the framed electric signal supplied from FEC decoder 22. When the successive number reaches the predetermined number, later stage frame asynchronization detection circuit 34 determines that the frame asynchronization state has occurred in the data signal and outputs a later stage frame asynchronization detection signal to receiver's frame synchronization indication output circuit 35. Later stage frame asynchronization detection circuit 34 has stored the predetermined number (predetermined value) based on which it determines that the frame asynchronization state has occurred.

Receiver's frame synchronization indication output circuit 35 outputs the receiver's frame synchronization indication signal that causes the frame synchronization establishment state to occur based on the frame synchronization detection signal supplied from earlier stage frame synchronization detection circuit 32 and that causes the frame asynchronization state to occur based on the later stage frame asynchronization detection signal supplied from later stage frame asynchronization detection circuit 34.

Frame termination circuit 21 removes synchronization words from the framed electric signal supplied from FEC decoder 22 and then reproduces the data signal.

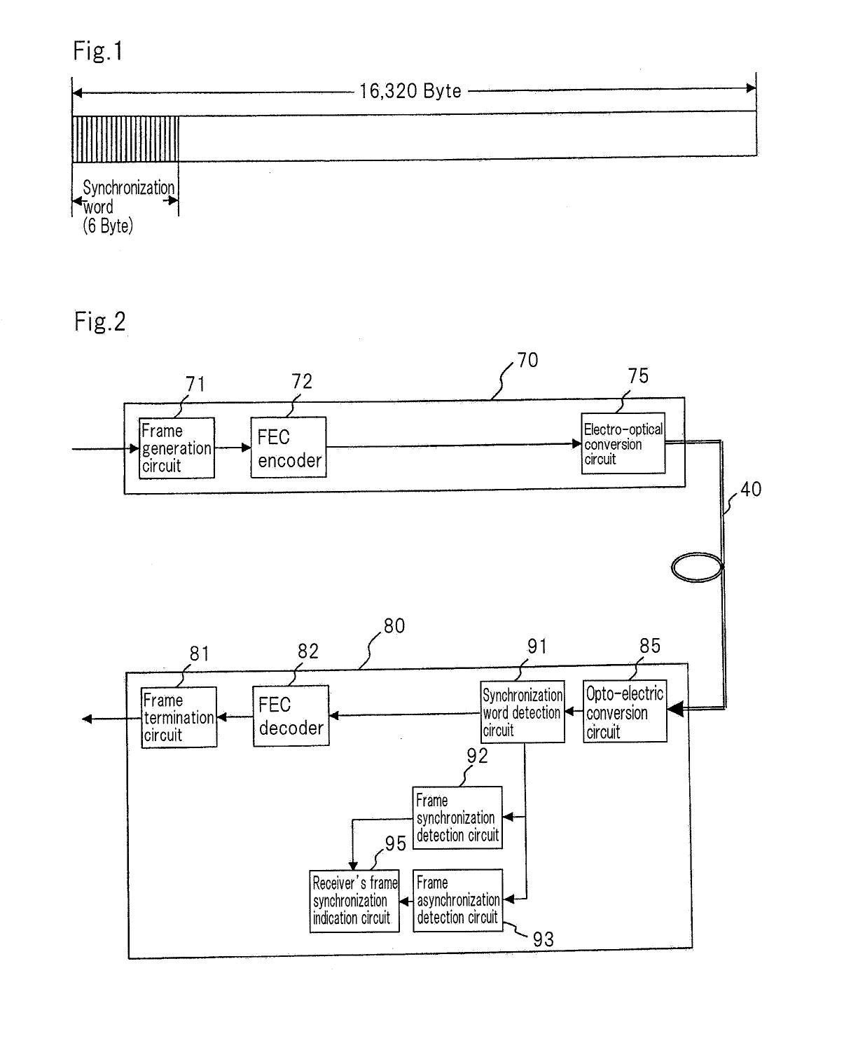

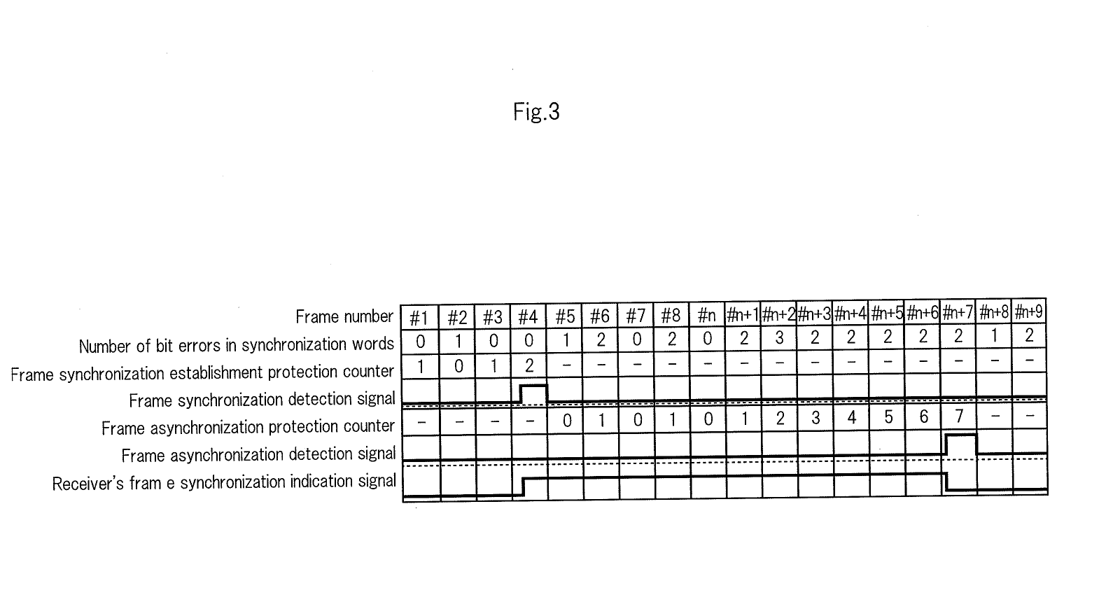

Optical reception device 20 converts the received optical signal into an electric signal and reproduces the error-correction-coded electric signal. Earlier stage synchronization word detection circuit 31 detects synchronization words from the error-correction-coded electric signal supplied from opto-electric conversion circuit 25. For example, in the frame structure shown in FIG. 1, a synchronization word composed of six bytes that are preseht at the beginning of the frame is detected. When earlier stage synchronization word detection circuit 31 detects a synchronization word, earlier stage synchronization word detection circuit 31 outputs a frame-synchronized error-correction-coded electric signal. Earlier stage frame synchronization detection circuit 32 counts the successive number of synchronization words in which no bit errors have been detected by earlier stage synchronization word detection circuit 31 using a synchronization protection counter (not shown). When the successive number of synchronization words reaches the predetermined number, earlier stage frame synchronization detection circuit 32 determines that a frame synchronization establishment state has occurred and outputs the frame synchronization detection signal. The predetermined number of the successive number of synchronization words that do not have bit errors is referred to as the number of frame synchronization detection protection stages. Receiver's frame synchronization indication output circuit 35 outputs the receiver's frame synchronization indication signal based on the frame synchronization detection signal supplied from earlier stage frame synchronization detection circuit 32. After receiver's frame synchronization indication output circuit 35 outputs the receiver's frame synchronization indication signal, earlier stage synchronization word detection circuit 31 may output the frame-synchronized error-correction-coded electric signal or frame termination circuit 21 may output a data signal.

FEC decoder 22 corrects errors of the frame-synchronized error-correction-coded electric signal including synchronization words supplied from earlier stage synchronization word detection circuit 31 and reproduces the framed electric signal. Since the error correction process has been performed for the framed electric signal, bit errors of the framed electric signal have decreased.

Later stage frame asynchronization detection circuit 34 counts the successive number of synchronization words that have bit errors in excess of the allowable value of the synchronization words contained in the framed electric signal supplied from FEC decoder 22. Later stage frame asynchronization detection circuit 34 counts the successive number of synchronization words that have bit errors using a later stage frame asynchronization protection counter (not shown). Since the positions of synchronization words are known, when later stage frame asynchronization detection circuit 34 accepts the framed electric signal, later stage frame asynchronization detection circuit 34 may compare a known synchronization word with a predetermined synchronization word and detect a bit error.

When the successive number of synchronization words that have bit errors reaches the predetermined number, later stage frame asynchronization detection circuit 34 determines that the frame asynchronization state has occurred and outputs the later stage frame asynchronization detection signal. The allowable value based on which later stage frame asynchronization detection circuit 34 outputs the later stage frame asynchronization detection signal represents the allowable limit of bit errors contained in the synchronization words and is also referred to as the allowable number of bit errors of synchronous words. When the number of bit errors that is allowable in synchronization words is 1, it denotes that even if one bit error occurs, it is counted. The predetermined number of the successive number of synchronization words that have bit errors is referred to as the number of frame asynchronization detection protection stages. Receiver's frame synchronization indication output circuit 35 outputs the receiver's frame synchronization indication signal based on the later stage frame asynchronization detection signal supplied from later stage frame asynchronization detection circuit 34.

When receiver's frame synchronization indication output circuit 35 outputs the receiver's frame synchronization indication signal, situations in which frame termination circuit 21 stops outputting the data signal, earlier stage synchronization word detection circuit 31 stops outputting the frame-synchronized error-correction-coded electric signal, and earlier stage synchronization word detection circuit 31 starts searching for synchronization words will occur.

According to this embodiment, since later stage frame asynchronization detection circuit 34 detects synchronization words that have bit errors in the error-correction-coded framed electric signal supplied form FEC decoder 22, the likelihood in which the frame asynchronization state occurs becomes low. Thus, later stage frame asynchronization detection circuit 34 does not frequently output the later stage frame asynchronization detection signal. As a result, situations in which frame termination circuit 21 stops outputting the data signal, earlier stage synchronization word detection circuit 31 stops outputting the frame-synchronized error-correction-coded electric signal, and earlier stage synchronization word detection circuit 31 starts searching for synchronization words will not frequently occur. In other words, optical reception device 20 will not be prone to enter a frame asynchronization state.

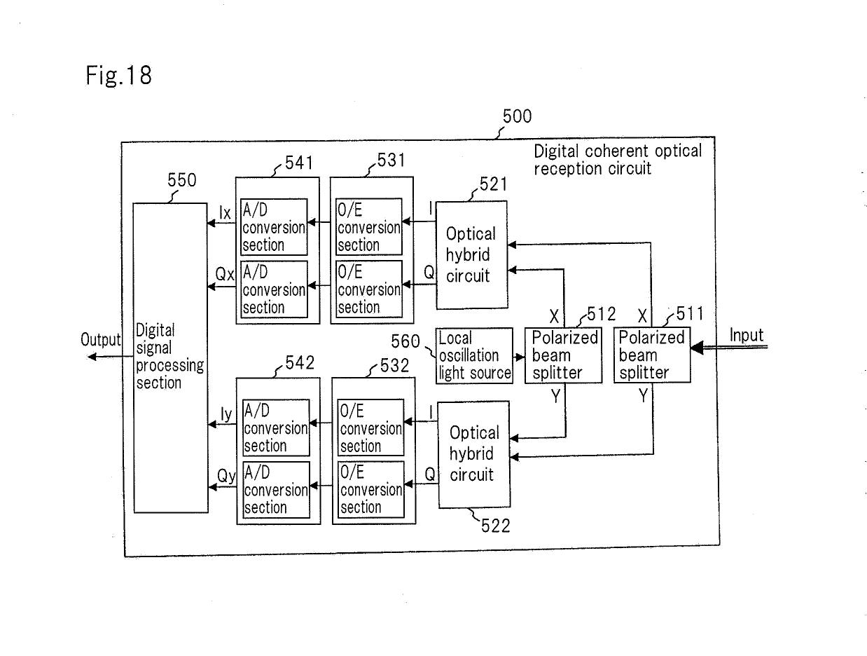

As an example of opto-electric conversion circuit 25 shown in FIG. 4, FIG. 18 shows an example of a digital coherent optical reception device. In FIG. 18, as an optical signal supplied from electro-optical conversion circuit 15, a digital coherent optical signal is input to digital coherent optical reception circuit 500. Digital coherent optical reception circuit 500 is provided with polarized beam splitters 511 and 512, optical hybrid circuits 521 and 522, O/E conversion sections 531 and 532, A/D conversion sections 541 and 542, digital signal processing section 550, and local oscillation light source 560.

Polarized beam splitters 511 and 512 split light into two orthogonal polarized components.

Optical hybrid circuits 521 and 522 combine light beams and separate them into I and Q components.

O/E conversion sections 531 and 532 convert an optical signal into an electric signal.

A/D conversion sections 541 and 542 converts an analog signal into a digital signal.

Digital signal processing section 550 perfoiins a digital process for an input digital signal and reproduces an original digital signal.

Local oscillation light source 560 oscillates light having the same or similar oscillation frequency as the input optical signal does.

When an optical signal that is supplied from electro-optical conversion circuit 15 is input to polarized beam splitter 511, the optical signal is split into X and Y polarized components. When an optical signal supplied from local oscillation light source 560 is input to polarized beam splitter 512, it splits the optical signal into X and Y polarized components. Polarized components in the same directions are combined by optical hybrid circuits 521 and 522 and the combined components are split into I and Q components. The split components are converted into electric signals by O/E conversion sections 531 and 532. The converted electric signals are converted into digital signals by A/D conversion sections 541 and 542 and output as an I component and Q component electric signals. Digital signal processing section 550 performs a digital process for the I and Q component electric signals so as to reproduce the original signal.

Digital coherent optical reception circuit 500 described above can be applied to opto-electric conversion circuits according to the embodiments that follow.

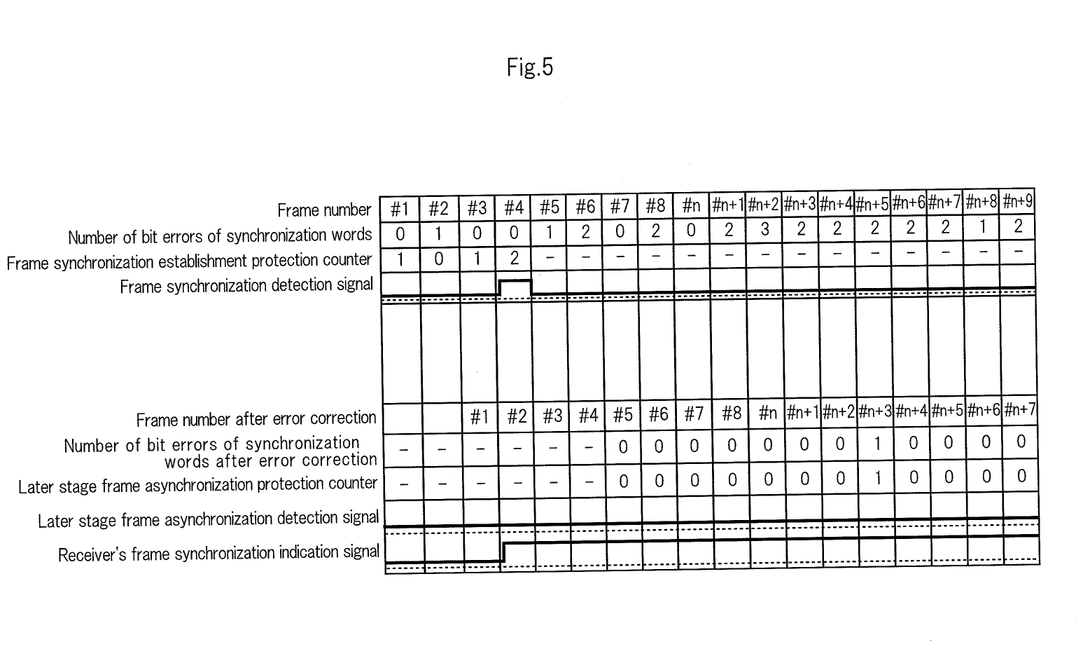

FIG. 5 is a schematic diagram showing an example of the operation of the optical reception device shown in FIG. 4. In FIG. 5, the number of frame synchronization detection protection stages is 2; the number of bit errors that is allowable in synchronization words is 1; the number of frame asynchronization detection protection stages is 7. It should be noted that these values are examples and therefore the present invention is not limited to these values. In FIG. 5, since bit errors have not occurred successively in synchronization words of frame numbers #3 and #4 (synchronization establishment protection counter becomes 2), earlier stage frame synchronization detection circuit 32 outputs the frame synchronization detection signal. As a result, receiver's frame synchronization indication output circuit 35 causes the receiver's frame synchronization indication signal to go high which represents the frame synchronization establishment state.

As shown in FIG. 5, since the number of bit errors in the synchronization words of an error-correction-coded signal is small, the value of the later stage asynchronization protection counter is almost “0.” Thus, since synchronization words that have bit errors are not successively detected, the later stage frame asynchronization detection signal will not be output. As a result, the receiver's frame synchronization indication signal will remain in a high state that represents the frame synchronization establishment state.

### Embodiment 2

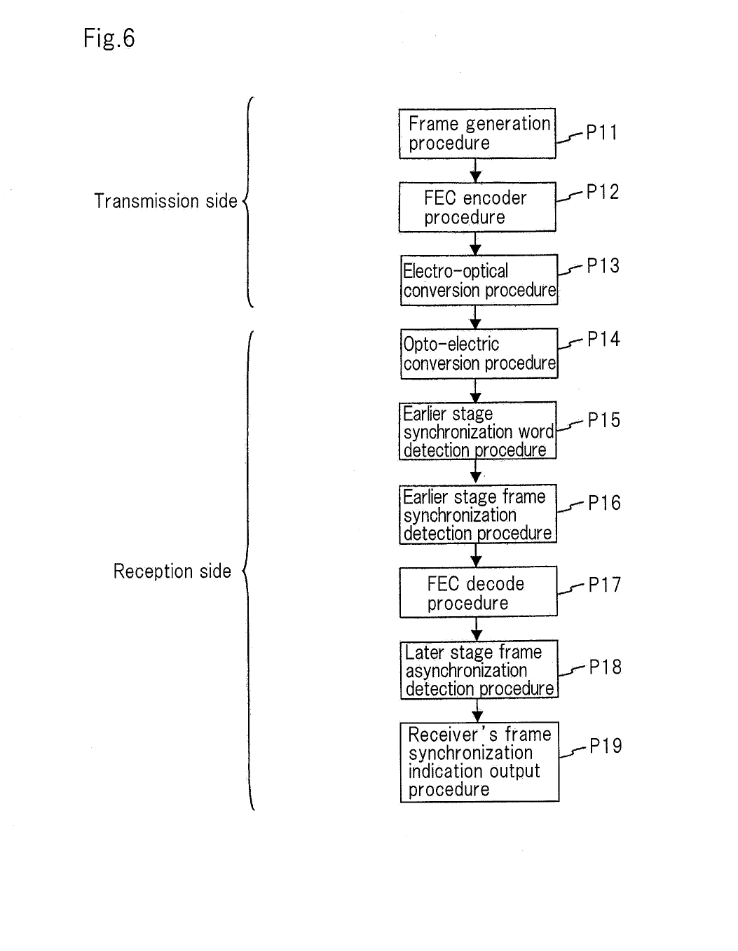

FIG. 6 is a schematic diagram showing an example of an optical transmission and reception method for an optical transmission and reception system according to this embodiment. In FIG. 6, frame generation circuit 11 adds synchronization words to an input data signal so as to generate a framed electric signal (at frame generation procedure P11). After frame generation procedure P11 is performed, FEC encoder 12 adds error correction code to the framed electric signal so as to generate an error-correction-coded electric signal (at FEC encode procedure P12). After FEC encode procedure P12, electro-optical conversion circuit 15 converts the error-correction-coded electric signal into an optical signal and transmits it (at electro-optical conversion procedure P13). After electro-optical conversion procedure P13, opto-electric conversion circuit 25 accepts the optical signal, converts the accepted optical signal into an electric signal, and reproduces the error-correction-coded electric signal (at opto-electric conversion procedure P14). After opto-electric conversion procedure P14, earlier stage synchronization word detection circuit 31 detects synchronization words from the error-correction-coded electric signal and outputs a frame-synchronized error-correction-coded electric signal (at earlier stage synchronization word detection procedure P15). After earlier stage synchronization word detection procedure P15, earlier stage frame synchronization detection circuit 32 counts the successive counts the successive number of synchronization words in which no bit errors have been detected by earlier stage synchronization word detection circuit 31, determines that the frame synchronization establishment state has occurred when the successive number reaches the predetermined number, and outputs the frame synchronization detection signal (at earlier stage frame synchronization detection procedure P16). After earlier stage frame synchronization detection procedure P16, FEC decoder 22 corrects errors of the frame-synchronized error-correction-coded electric signal including synchronization words and reproduces the framed electric signal (at FEC decode procedure P17). After FEC decode procedure P17, later stage frame asynchronization detection circuit 34 counts the successive number of synchronization words that have bit errors in excess of the allowable value of the synchronization words contained in the framed electric signal, determines that a frame asynchronization state has occurred when the successive number reaches the predetermined number, and outputs the later stage frame asynchronization detection signal (at later stage frame asynchronization detection procedure P18). Receiver's frame synchronization indication output circuit 35 outputs the receiver's frame synchronization indication signal based on the later stage frame asynchronization detection signal that is output at the later stage frame asynchronization detection procedure P18 (at receiver's frame synchronization indication output procedure P19).

According to this embodiment, at later stage frame asynchronization detection procedure P18, synchronization words that have bit errors are detected from the framed electric signal whose errors have been corrected at the FEC decode procedure P17. Thus, the number of bit errors contained in synchronization words is small. As a result, later stage frame asynchronization detection circuit 34 does not frequently output the later stage frame asynchronization detection signal. Consequently, situations in which the optical transmission and reception system stop outputting the data signal, stop outputting the frame-synchronized error-correction-coded electric signal, and start searching for synchronization words will not frequently occur. In other words, the optical transmission and reception system will not be prone to enter a frame asynchronization state.

### Embodiment 3

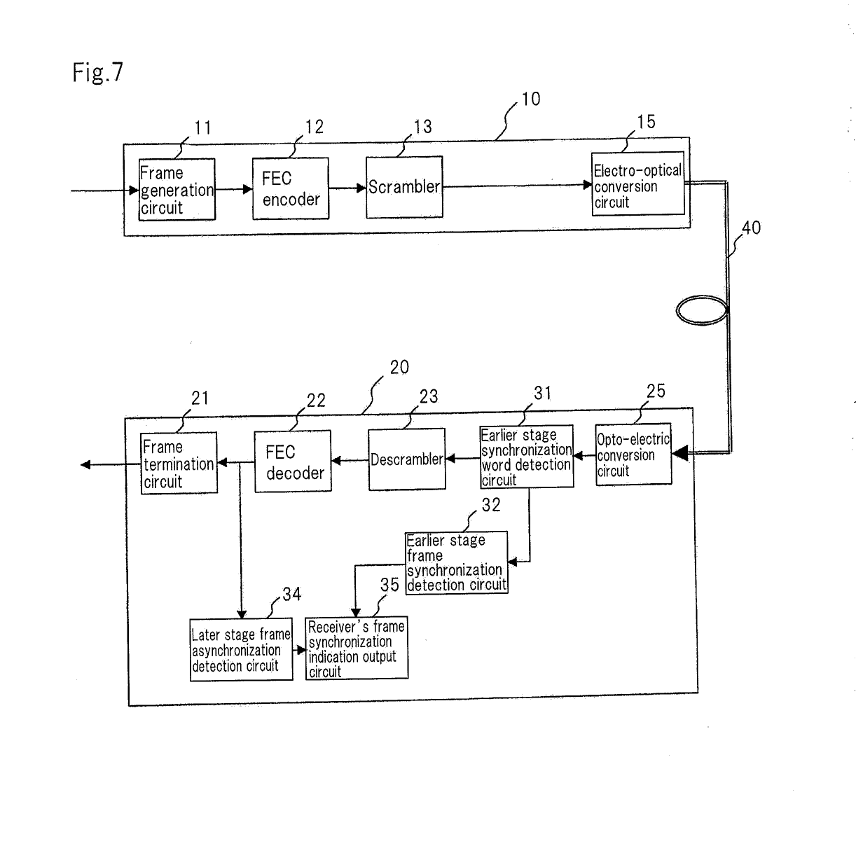

FIG. 7 is a schematic diagram showing an example of the structure of an optical transmission and reception system according to this embodiment. This embodiment is different from embodiment 1 in that optical transmission device 10 is also provided with scrambler 13 between FEC encoder 12 and electro-optical conversion circuit 15 and optical reception device 20 is also provided with descrambler 23 between earlier stage synchronization word detection circuit 31 and FEC decoder 22.

Scrambler 13 scrambles an error-correction-coded electric signal supplied from FEC encoder 12 with a pseudo random signal. Scrambling can prevent bits with “0” and “1” having the same sign successively from being generated and can cause occurrence probabilities of “0” and “1” to become equal. Descrambler 23 descrambles the scrambled signal. Although the optical transmission and reception system according to this embodiment is also provided with scrambler 13 and descrambler 23, this system has the same effect as the system according to embodiment 1 does.

### Embodiment 4

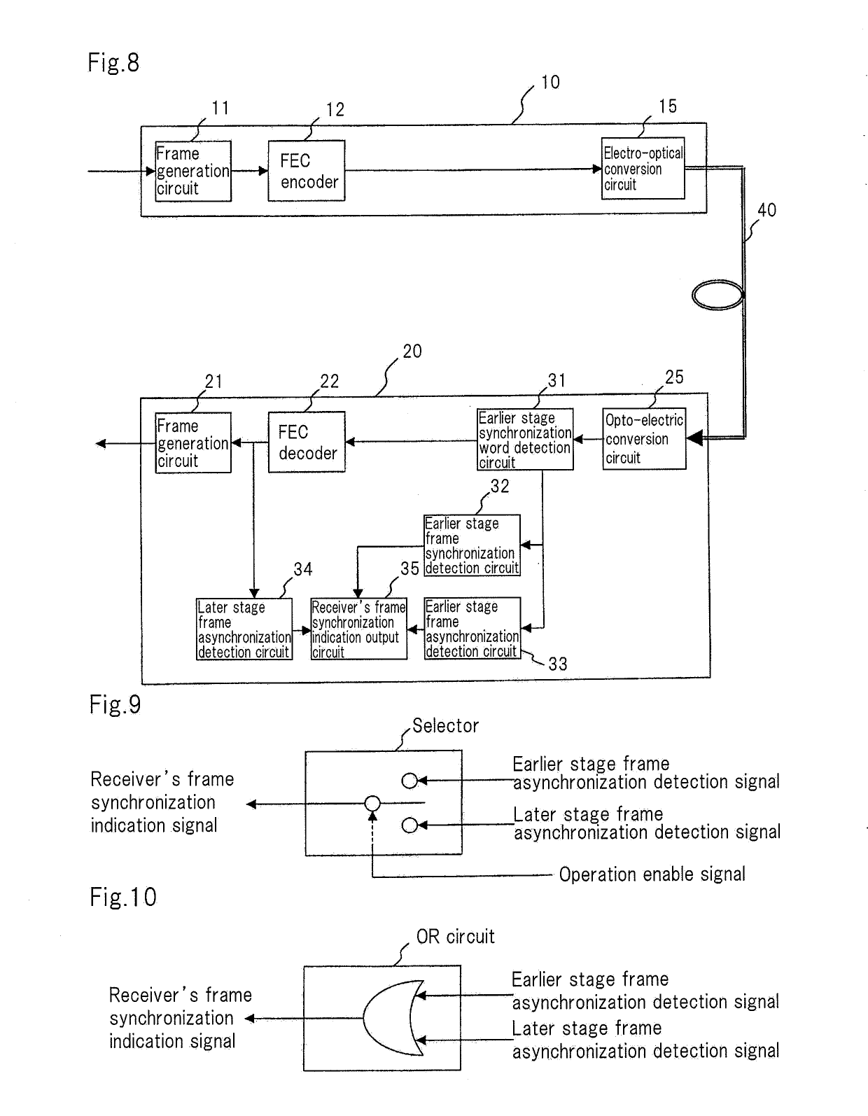

FIG. 8 is a schematic diagram showing an example of the structure of an optical transmission and reception system according to this embodiment. This embodiment is different from embodiment 1 in that optical reception device 20 is also provided with earlier stage frame asynchronization detection circuit 33.

According to this embodiment, earlier stage frame asynchronization detection circuit 33 counts the successive number of synchronization words that have bit errors in excess of an allowable value of the synchronization words detected by earlier stage synchronization word detection circuit 31, determines that a frame asynchronization state has occurred when the successive number reaches a predetermined number, and outputs an earlier stage frame asynchronization detection signal to receiver's frame synchronization indication output circuit 35. Earlier stage frame asynchronization detection circuit 33 has stored the allowable value based on which it outputs the earlier stage frame asynchronization detection signal.

Receiver's frame synchronization indication output circuit 35 outputs the receiver's frame synchronization indication signal that causes the frame synchronization establishment state to occur based on the frame synchronization detection signal supplied from earlier stage frame synchronization detection circuit 32 and that causes a frame asynchronization state to occur based on the earlier stage frame asynchronization detection signal supplied from earlier stage frame asynchronization detection circuit 33 or based on the later stage frame asynchronization detection signal supplied from later stage frame asynchronization detection circuit 34.

Receiver's frame synchronization indication output circuit 35 selects either the earlier stage frame asynchronization detection signal supplied from earlier stage frame asynchronization detection circuit 33 or the later stage frame asynchronization detection signal supplied from later stage frame asynchronization detection circuit 34.

FIG. 9 is a schematic diagram showing an example of a selector used for receiver's frame synchronization indication output circuit 35. After earlier stage frame synchronization detection circuit 32 determines that a frame synchronization establishment state has occurred, the selector causes the frame asynchronization state to occur based on the later stage frame asynchronization detection signal supplied from later stage frame asynchronization detection circuit 34. This determination results in the generation of an operation enable signal. The selector is an internal circuit of receiver's frame synchronization indication output circuit 35 and the operation enable signal represents the internal state of receiver's frame synchronization indication output circuit 35.

According to this embodiment, after the frame synchronization establishment state has occurred, receiver's frame synchronization indication output circuit 35 causes the frame asynchronization state to occur based on the later stage frame asynchronization detection signal supplied from later stage frame asynchronization detection circuit 34. Since later stage frame asynchronization detection circuit 34 detects synchronization words that have bit errors from the error-correction-coded framed electric signal that is output from FEC decoder 22, the likelihood in which the frame asynchronization state occurs will be low. Thus, later stage frame asynchronization detection circuit 34 will not unconditionally output the later stage frame asynchronization detection signal. As a result, situations in which frame termination circuit 21 stops outputting the digital signal, earlier stage synchronization word detection circuit 31 stops outputting the frame-synchronized error-correction-coded electric signal, and earlier stage synchronization word detection circuit 31 starts searching for synchronization words will not frequently occur. In other words, the optical transmission and reception system will not be prone to enter a frame asynchronization state.

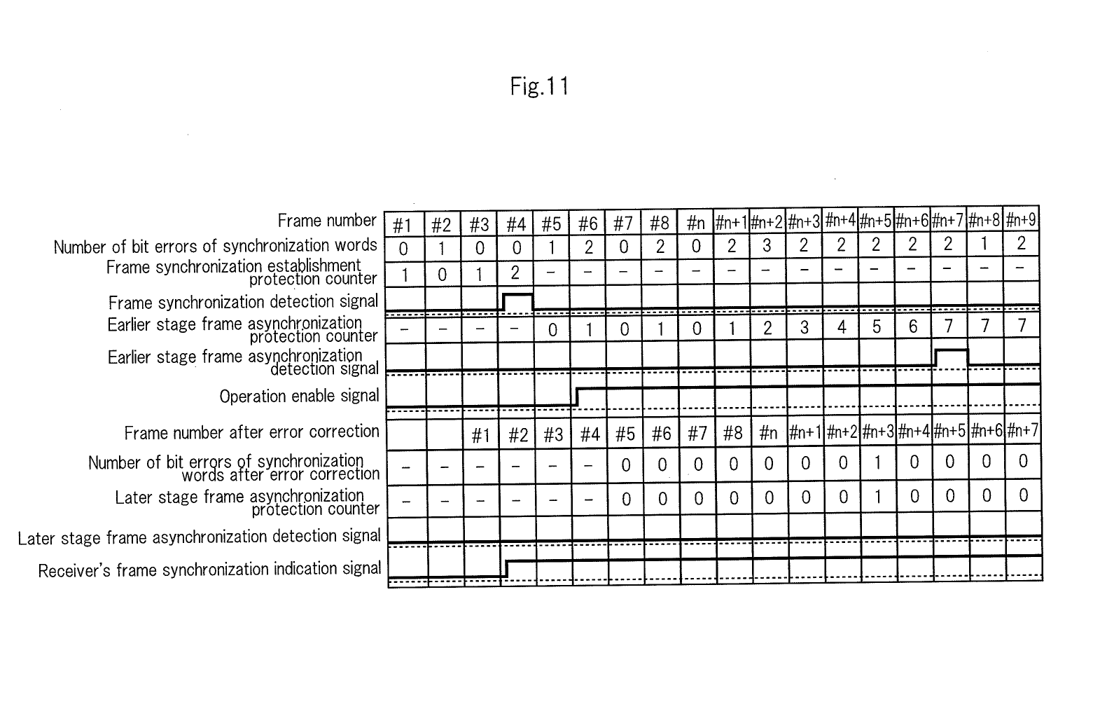

FIG. 11 is a schematic diagram showing an example of the operation of the optical reception device shown in FIG. 8. In FIG. 11, the number of frame synchronization detection protection stages is 2; the number of bit errors that is allowable in synchronization words is 1; the number of earlier frame asynchronization detection protection stages is equal to the number of later stage frame asynchronization detection protection stages and is 7. It should be noted that these values are examples and therefore the present invention is not limited to these values. Since bit errors have not occurred successively in synchronization words of frame numbers #3 and #4 (synchronization establishment protection counter becomes 2), earlier stage frame synchronization detection circuit 32 outputs the frame synchronization detection signal. As a result, receiver's frame synchronization indication output circuit 35 causes the receiver's frame synchronization indication signal to go high which represents the frame synchronization establishment state.

In the operation enable signal shown in FIG. 11, process delays that will occur in FEC decoder 22 and later stage frame asynchronization detection circuit 34 are taken into consideration and therefore two frames after the synchronization detection signal is output, the operation enable signal goes high. After the operation enable signal goes high until the later stage frame asynchronization detection signal is output, the receiver's frame synchronization indication signal remains high which represents the frame synchronization establishment state.

### Embodiment 5

The structure of an optical transmission and reception system according to this embodiment is the same as that of the optical transmission and reception system shown in FIG. 8.

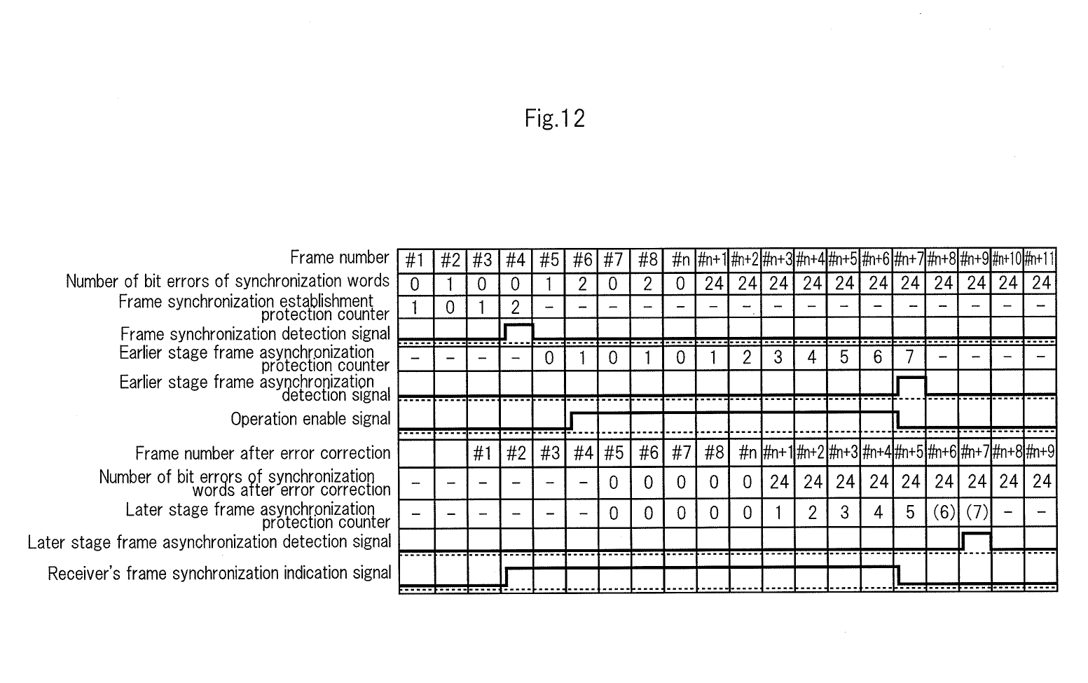

FIG. 12 is a schematic diagram showing an example of the operation of the optical reception device according to embodiment 5. In FIG. 12, receiver's frame synchronization indication output circuit 35 operates in the same manner as the receiver's frame synchronization indication output circuit operates according to embodiment 4 does until receiver's frame synchronization indication output circuit 35 causes the receiver's frame synchronization indication signal to go high which represents the frame synchronization establishment state. However, when either the earlier stage frame asynchronization detection signal or the later stage frame asynchronization detection signal is output to receiver's frame synchronization indication output circuit 35, it causes the operation enable signal to change from the high state to the low state. The selector shown in FIG. 9 decides the operation of the receiver's frame synchronization indication signal based on the earlier stage frame asynchronization detection signal as the operation enable signal changes from the high state to the low state. FIG. 10 shows another method in which receiver's frame synchronization indication output circuit 35 outputs the receiver's frame synchronization indication signal based on the earlier stage frame asynchronization detection signal.

FIG. 10 is a schematic diagram showing an OR circuit used for receiver's frame synchronization indication output circuit 35. After the frame synchronization establishment state has occurred, when either the earlier stage frame asynchronization detection signal or the later stage frame asynchronization detection signal is output, receiver's frame synchronization indication output circuit 35 causes the receiver's frame synchronization indication signal to go low. Alternatively, receiver's frame synchronization indication output circuit 35 may cause the frame asynchronization state to occur only based on the earlier stage frame asynchronization detection signal.

When the frame asynchronization state actually occurs, assuming that the occurrence probabilities of “1” and “0” are 0.5 each and that the synchronization word is 6 bytes long, the number of error bits of a synchronization word would become 24 bits. In this case, earlier stage frame asynchronization detection circuit 33 can detect the frame asynchronization state more quickly than later stage frame asynchronization detection circuit 34. Thus, earlier stage synchronization word detection circuit 31 can quickly start searching for synchronization words.

However, it is preferable that the allowable value of the number of bit errors of earlier stage frame asynchronization detection circuit 33 should be greater than that of later stage frame asynchronization detection circuit 34. For example, it is assumed that the number of frame synchronization detection protection stages is 2; the number of bit errors that is allowable in synchronization words when the frame asynchronization state is detected in the earlier stage is 5; the number of bit errors that is allowable in synchronization words when the frame asynchronization state is detected in the later state is 1; the number of earlier stage frame asynchronization detection protection stages is equal to the number of later stage frame asynchronization detection protection stages and is 7. It should be noted that these values are examples and therefore the present invention is not limited to these values. These settings allow earlier stage frame asynchronization detection circuit 33 to detect the frame asynchronization state more quickly than later stage frame asynchronization detection circuit 34 does and also the likelihood in which earlier stage frame asynchronization detection circuit 33 determines that the frame asynchronization state has occurred with small number of bit errors will decrease.

### Embodiment 6

The structure of the optical transmission and reception system according to this embodiment is the same as that of the optical transmission and reception system shown in FIG. 8.

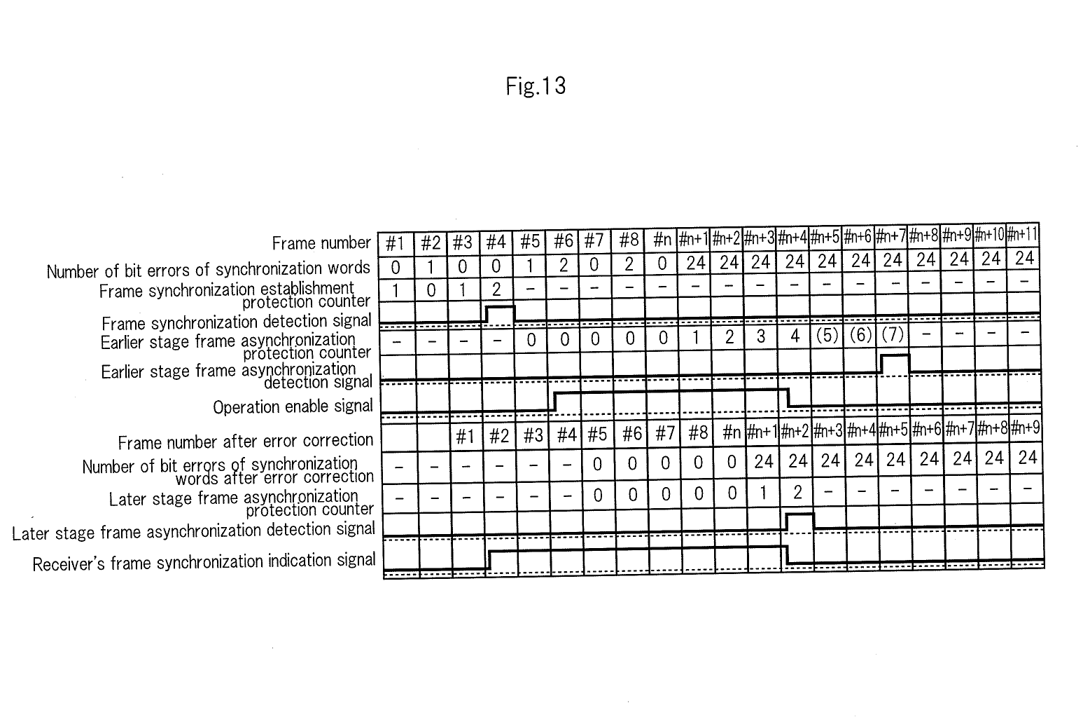

FIG. 13 is a schematic diagram showing an example of the operation of the optical reception device according to embodiment 6. In FIG. 13, receiver's frame synchronization indication output circuit 35 operates in the same manner as the receiver's frame synchronization indication output circuit operates according to embodiment 4 does until receiver's frame synchronization indication output circuit 35 causes the receiver's frame synchronization indication signal to go high which represents the frame synchronization establishment state. However, when either the earlier stage frame asynchronization detection signal or the later stage frame asynchronization detection signal is output to receiver's frame synchronization indication output circuit 35, it causes the operation enable signal to change from the high state to the low state. The selector shown in FIG. 9 decides the operation of a receiver's frame synchronization indication signal based on the earlier stage frame asynchronization detection signal as the operation enable signal changes from the high state to the low state.

In FIG. 10, after the frame synchronization establishment state has occurred, when either the earlier stage frame asynchronization detection signal or the later stage frame asynchronization detection signal is output to receiver's frame synchronization indication output circuit 35, it causes the receiver's frame synchronization indication signal to go low. Alternatively, receiver's frame synchronization indication output circuit 35 can cause the frame asynchronization state to occur only based on the later stage frame asynchronization detection signal.

When the frame asynchronization state actually occurs, assuming that the occurrence probabilities of “1” and “0” are 0.5 each and that the synchronization word is 6 bytes long, the number of error bits in a synchronization word would become 24 bits. In this case, it is preferable that the predetermined number of the successive number of synchronization words that have bit errors in excess of the allowable value of later stage frame asynchronization detection circuit 34 be smaller than the predetermined number of the successive number of synchronization words that have bit errors in excess of the allowable value of earlier stage frame asynchronization detection circuit 33. For example, it is assumed that the number of frame synchronization detection protection stages is 2; the number of bit errors that is allowable in synchronization words when the frame asynchronization state is detected in the earlier stage is 1; the number of bit errors that is allowable in synchronization words when the frame asynchronization state is detected in the later stage is 1; the number of earlier stage frame asynchronization detection protection stages is 7; and the number of later stage frame asynchronization detection protection stages is 2. It should be noted that these values are examples and therefore this embodiment is not limited to these values.

In this case, later stage frame asynchronization detection circuit 34 can detect the frame asynchronization state more quickly than earlier stage frame asynchronization detection circuit 33. Thus, earlier stage synchronization word detection circuit 31 can quickly start searching for synchronization words. Also the likelihood in which earlier stage frame asynchronization detection circuit 33 determines that the frame asynchronization state occurs with a small number of bit errors will decrease.

### Embodiment 7

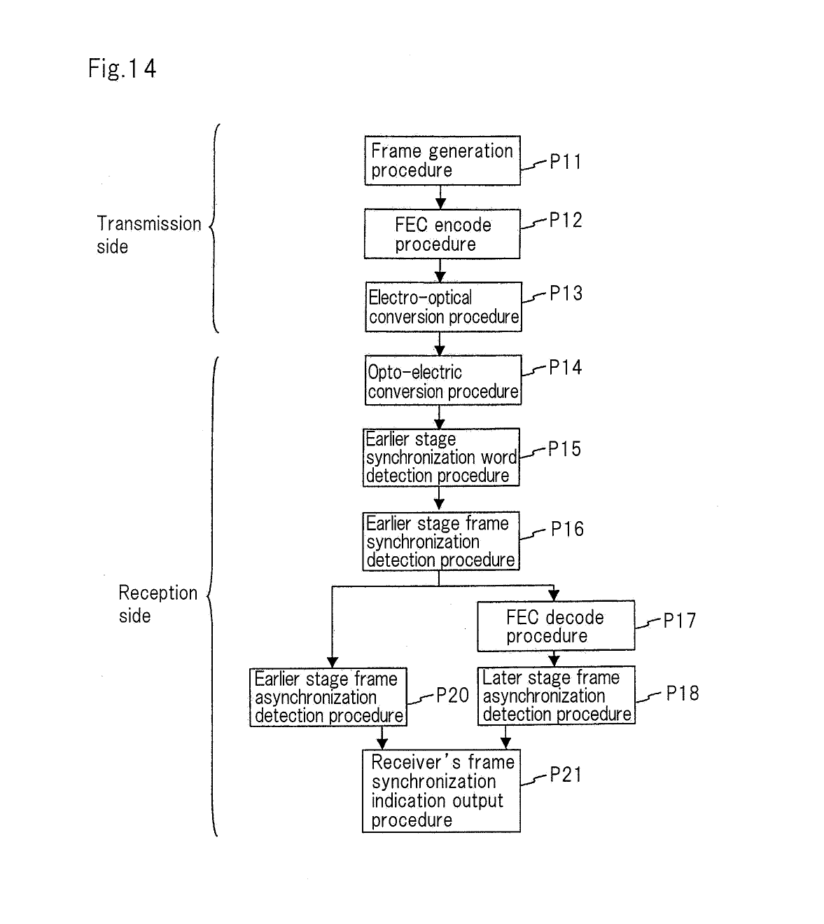

FIG. 14 is a schematic diagram showing an example of an optical transmission and reception method for an optical transmission and reception system according to this embodiment. In FIG. 14, frame generation circuit 11 adds synchronization words to an input data signal so as to generate a framed electric signal (at frame generation procedure P11). After frame generation procedure P11, FEC encoder 12 adds error correction code to the framed electric signal so as to generate an error-correction-coded electric signal (at FEC encode procedure P12).

After FEC encode procedure P12 is performed, then, electro-optical conversion circuit 15 converts the error-correction-coded electric signal into an optical signal and transmits it (at electro-optical conversion procedure P13). After the electro-optical conversion procedure P13 is performed, opto-electric conversion circuit 25 accepts the optical signal, converts the accepted optical signal into an electric signal, and reproduces the error-correction-coded electric signal (at opto-electric conversion procedure P14). After the opto-electric conversion procedure P14 is performed, earlier stage synchronization word detection circuit 31 detects synchronization words from the error-correction-coded electric signal and outputs a frame-synchronized error-correction-coded electric signal (at earlier stage synchronization word detection procedure P15).

After earlier stage synchronization word detection procedure P15 is performed, earlier stage frame synchronization detection circuit 32 counts the successive number of synchronization words in which no bit errors have been detected by earlier stage synchronization word detection circuit 31, determines that the frame synchronization establishment state has occurred when the successive number reaches the predetermined number, and outputs the frame synchronization detection signal (at earlier stage frame synchronization detection procedure P16). After the earlier stage frame synchronization detection procedure P16 is performed, FEC decoder 22 corrects errors of the frame-synchronized error-correction-coded electric signal including synchronization words and reproduces the framed electric signal (at FEC decode procedure P17).

After FEC decode procedure P17 is performed, later stage frame asynchronization detection circuit 34 counts the successive number of synchronization words that have bit errors in excess of the allowable value of the synchronization words contained in the framed electric signal, determines a the frame asynchronization state has occurred when the successive number reaches the predetermined number, and outputs the later stage frame asynchronization detection signal (at later stage frame asynchronization detection procedure P18). Later stage frame asynchronization detection circuit 34 has stored the allowable value based on which it outputs the later stage frame asynchronization detection signal.

After earlier stage synchronization word detection procedure P15 is performed, earlier stage frame asynchronization detection circuit 33 counts the successive number of synchronization words in which no bit errors have been detected by the earlier stage synchronization word detection procedure P15, determines that a frame asynchronization state has occurred when the successive number reaches the predetermined number, and outputs the earlier stage frame asynchronization detection signal (at earlier stage frame asynchronization detection procedure P20). Earlier stage frame asynchronization detection circuit 33 has stored the allowable value based on which it outputs the earlier stage frame asynchronization detection signal.

Receiver's frame synchronization indication output circuit 35 outputs a receiver's frame synchronization indication signal that causes the frame asynchronization state to occur based on the earlier stage frame asynchronization detection signal detected at the earlier stage frame asynchronization detection procedure P20 or based on the later stage frame asynchronization detection signal detected by the later stage frame asynchronization detection procedure P18 (at receiver's frame synchronization indication output procedure P21).

According to this embodiment, later stage frame asynchronization detection circuit 34 accepts an error-correction-coded framed electric signal from FEC decoder 22 and detects synchronization words that have bit errors from the framed electric signal. Thus, later stage frame asynchronization detection circuit 34 would not unconditionally output the later stage frame asynchronization detection signal. Since receiver's frame synchronization indication output circuit 35 causes the optical transmission and reception system to enter a frame asynchronization state based on the later stage frame asynchronization detection signal or the earlier stage frame asynchronization detection signal, situations in which the optical transmission and reception system stops outputting the data signal, stops outputting the frame-synchronized error-correction-coded electric signal, and starts searching for synchronization words will not frequently occur.

After the receiver's frame synchronization indication output procedure P21, then receiver's frame synchronization indication output circuit 35 may cause the frame asynchronization state to occur when either the earlier stage frame asynchronization detection signal or the later stage frame asynchronization detection signal is output, or it may cause the frame asynchronization state to occur only based on the later stage frame asynchronization detection signal.

According to this embodiment, at the later stage frame asynchronization detection procedure P18, after errors are corrected, the frame asynchronization state is detected. Thus, the later stage frame asynchronization detection signal would not be unconditionally output. In addition, when either the earlier stage frame asynchronization detection signal or the later stage frame asynchronization detection signal is output when the receiver's frame synchronization indication output procedure P21 is performed, if the frame asynchronization state occurs, it can be quickly detected. Thus, earlier stage synchronization word detection circuit 31 can quickly start searching for synchronization words.

It is preferable that the allowable value of the number of bit errors at the earlier stage frame asynchronization detection procedure P20 be greater than the allowable value of the number of bit errors at later stage frame asynchronization detection procedure P18. In this case, after the receiver's frame synchronization indication output procedure P21 is performed, receiver's frame synchronization indication output circuit 35 may cause the frame asynchronization state to occur when either the earlier stage frame asynchronization detection signal or the later stage frame asynchronization detection signal is output, or it may cause the frame asynchronization state to occur only based on the earlier stage frame asynchronization detection signal.

For example, it is assumed that the number of frame synchronization detection protection stages is 2; the number of bit errors that is allowable in synchronization words when the frame asynchronization state is detected in the earlier stage is 5; the number of bit errors that is allowable in synchronization words when the frame asynchronization state is detected in the later stage is 1; the number of earlier stage frame asynchronization detection protection stages is equal to the number of later stage frame asynchronization detection protection stages and is 7. It should be noted that these values are examples and therefore the present invention is not limited to these values. These settings allow the frame asynchronization state to be more quickly detected at earlier stage frame asynchronization detection procedure P20 than at later stage frame asynchronization detection procedure P18. Also the likelihood in which it is determined that the frame asynchronization state has occurred with a small number of bit errors at earlier stage frame asynchronization detection procedure P20 will decrease.

It is preferable that the predetermined number of the successive number of synchronization words that have bit errors in excess of the allowable value at the later stage frame asynchronization detection procedure P18 be smaller than the predetermined number of the successive number of synchronization words that have bit errors in excess of the allowable value at the earlier stage frame asynchronization detection procedure P20. In this case, after the receiver's frame synchronization indication output procedure P21, then receiver's frame synchronization indication output circuit 35 may cause the frame asynchronization state to occur when either the earlier stage frame asynchronization detection signal or the later stage frame asynchronization detection signal is output, or it may cause the frame, asynchronization state to occur only based on the later stage frame asynchronization detection signal.

For example, it is assumed that the number of frame synchronization detection protection stages is 2; the number of bit errors that is allowable in synchronization words when the frame asynchronization state is detected in the earlier stage is 1; the number of bit errors that is allowable in synchronization words when the frame asynchronization state is detected in the later stage is 1; the number of earlier stage frame asynchronization detection protection stages is 7; and the number of later stage frame asynchronization detection protection stages is 2. It should be noted that these values are examples and therefore the present invention is not limited to these values.

These settings allow the frame asynchronization state to be more quickly detected at later stage frame asynchronization detection procedure P18 than at earlier stage frame asynchronization detection procedure P20. Thus, earlier stage synchronization word detection circuit 31 can quickly start searching for synchronization words. Also the likelihood in which it is determined that the frame asynchronization state has occurred with a small number of bit errors at the earlier stage frame asynchronization detection procedure P20 will decrease.

### Embodiment 8

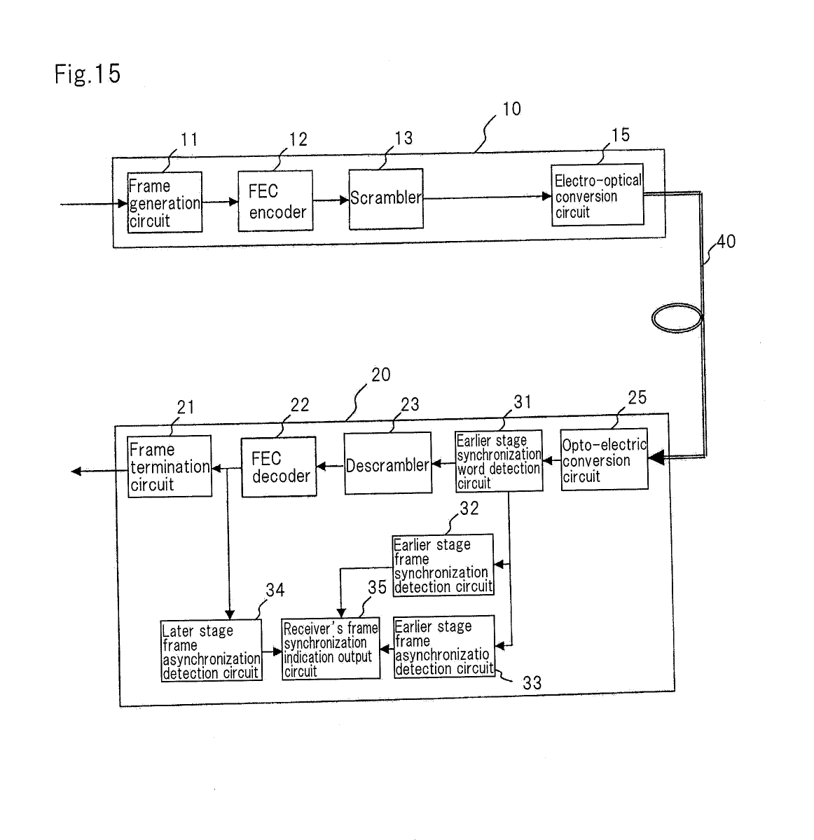

FIG. 15 is a schematic diagram showing an example of the structure of an optical transmission and reception system according to this embodiment. This embodiment is different from embodiments 4, 5, and 6 in that optical transmission device 10 is also provided with scrambler 13 between FEC encoder 12 and electro-optical conversion circuit 15 and optical reception device 20 is also provided with descrambler 23 between earlier stage synchronization word detection circuit 31 and FEC decoder 22.

Scrambler 13 scrambles an error-correction-coded electric signal supplied from FEC encoder 12 with a pseudo random signal. Scrambling can prevent bits with “0” and “1” having the same sign from being successively generated and can cause occurrence probabilities of “0” and “1” to become equal. Descrambler 23 descrambles the scrambled signal. Although the optical transmission and reception system according to this embodiment is also provided with scrambler 13 and descrambler 23, this system has the same effect as the systems according to embodiments 4, 5, and 6 do.

### Embodiment 9

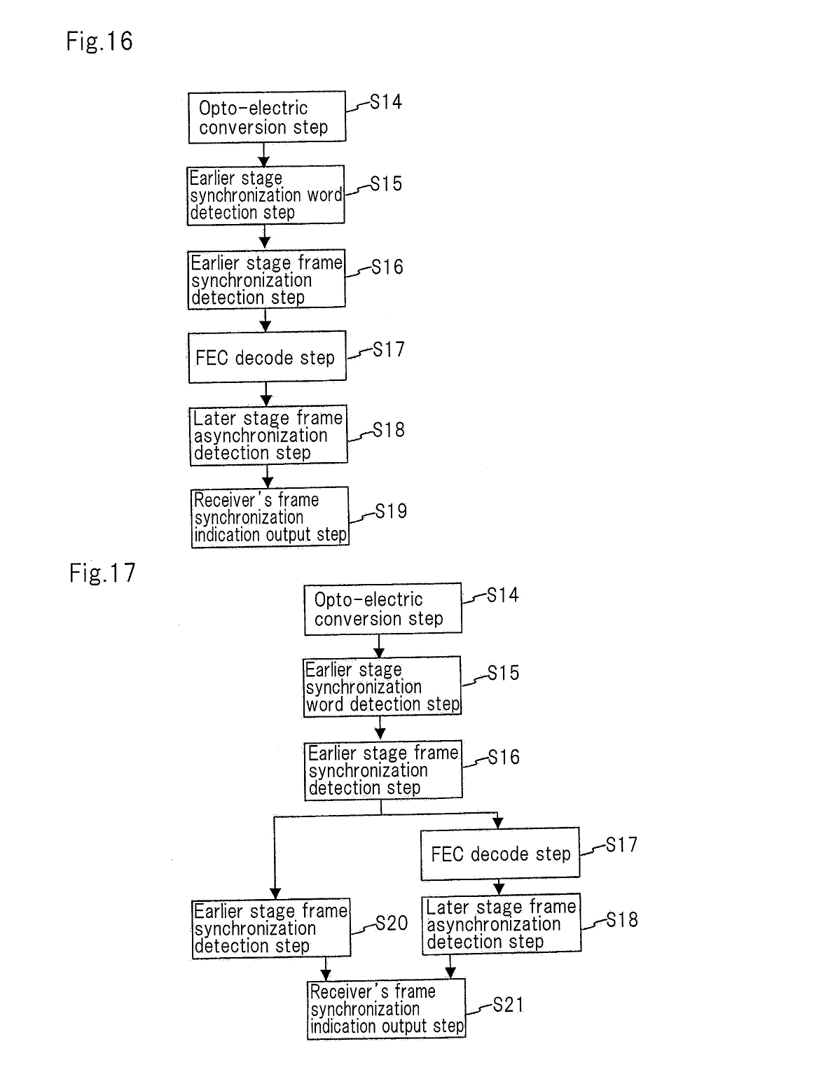

FIG. 16 is a schematic diagram showing an example of procedures of an optical reception program according to this embodiment. In FIG. 16, a computer that is used as an optical reception device executes the optical reception program.

The computer accepts an optical signal, converts the accepted optical signal into an electric signal, and reproduces an error-correction-coded electric signal (at opto-electric conversion step S14). After opto-electric conversion step S14, the computer detects synchronization words from the error-correction-coded electric signal and outputs a frame-synchronized error-correction-coded electric signal (at earlier stage synchronization word detection step S15).

After earlier stage synchronization word detection step S15, the computer counts the successive number of synchronization words that do not have bit errors of the synchronization words detected at the earlier stage synchronization word detection step S15, determines that a frame synchronization establishment state has occurred when the successive number reaches the predetermined number, and outputs a frame synchronization detection signal (at earlier stage frame synchronization detection step S16). After earlier stage frame synchronization detection step S16, the computer corrects errors of the frame-synchronized error-correction-coded electric signal including synchronization words and reproduces a framed electric signal (at FEC decode step S17).

After FEC decode step S17, the computer counts the successive number of synchronization words that have bit errors in excess of an allowable value of synchronization words contained in the framed electric signal, determines that the frame asynchronization state has occurred when the successive number reaches the predetermined number, and outputs a later stage frame asynchronization detection signal (at later stage frame asynchronization detection step S18). The computer outputs a receiver's frame synchronization indication signal that causes a frame asynchronization state to occur based on the later stage frame asynchronization detection signal detected at the later stage frame asynchronization detection step S18 (at receiver frame synchronization indication output step S19).

According to this embodiment, synchronization words that have bit errors are detected in the error-correction-coded framed electric signal at the FEC decode step S17, therefore the later stage frame asynchronization detection signal will not be unconditionally output. As a result, since the later stage frame asynchronization detection signal causes the frame asynchronization state to occur in the data signal based on the earlier stage frame asynchronization detection signal, situations in which the computer that is used as the optical reception device stops outputting the data signal, stops outputting the frame-synchronized error-correction-coded electric signal, and starts searching for synchronization words will not frequently occur. In other words, the computer that is used as the optical reception device will not be prone to enter a frame asynchronization state.

### Embodiment 10

FIG. 17 is a schematic diagram showing an example of procedures of an optical reception program according to this embodiment. In FIG. 17, a computer that is used as an optical reception device executes the optical reception program.

The computer accepts an optical signal, converts the accepted optical signal into an electric signal, and reproduces an error-correction-coded electric signal (at opto-electric conversion step S14). After the opto-electric conversion step S14, the computer detects synchronization words from the error-correction-coded electric signal and outputs a frame-synchronized error-correction-coded electric signal (at earlier stage synchronization word detection step S15).

After earlier stage synchronization word detection step S15, the computer counts the successive number of synchronization words that do not have bit errors of the synchronization words detected at earlier stage synchronization word detection step S15, determines that a frame synchronization establishment state has occurred when the successive number reaches the predetermined number, and outputs a frame synchronization detection signal (at earlier stage frame synchronization detection step S16). After earlier stage frame synchronization detection step S16, the computer corrects errors of the frame-synchronized error-correction-coded electric signal including synchronization words and reproduces a framed electric signal (at FEC decode step S17).

After FEC decode step S17, the computer counts the successive number of synchronization words that have bit errors in excess of an allowable value of synchronization words contained in the framed electric signal, deteimines that a frame asynchronization state has occurred when the successive number reaches the predetermined number, and outputs a later stage frame asynchronization detection signal (at later stage frame asynchronization detection step S18).

After earlier stage frame synchronization detection step S16, the computer counts the successive number of synchronization words that do not contain bit errors of the synchronization words detected at earlier stage synchronization word detection step S15, determines that a frame asynchronization state has occurred when the successive number reaches the predetei mined number, and outputs an earlier stage frame asynchronization detection signal (at earlier stage frame synchronization detection step S20). The computer outputs a receiver's frame synchronization indication signal that causes a frame asynchronization state to occur based on the earlier stage frame asynchronization detection signal detected at earlier stage frame asynchronization detection step S20 or based on the later stage frame asynchronization detection signal detected at the later stage frame asynchronization detection step S18 (at receiver's frame synchronization indication output step S21).

According to this embodiment, synchronization words that have bit errors are detected in the error-correction-coded framed electric signal at the FEC decode step S17, thus the later stage frame asynchronization detection signal would not be unconditionally output. In addition, since the computer that is used as the optical reception device causes the frame asynchronization state to occur based on the later stage frame asynchronization detection signal or the earlier stage frame asynchronization detection signal, situations in which the computer stops outputting the data signal, stops outputting the frame-synchronized error-correction-coded electric signal, and starts searching for synchronization words will not frequently occur.

At receiver's frame synchronization indication output step S21, the computer that is used as the optical reception device may cause a frame asynchronization state to occur when either the earlier stage frame asynchronization detection signal or the later stage frame asynchronization detection signal is output, or it may cause the frame asynchronization state to occur only based on the later stage frame asynchronization detection signal.

According to this embodiment, at later stage frame asynchronization detection step S20, after errors are corrected, the frame asynchronization state is detected. Thus, the later stage frame asynchronization detection signal will not be unconditionally output. In addition, when either the earlier stage frame asynchronization detection signal or the later stage frame asynchronization detection signal is input at receiver's frame synchronization indication output step S21, if the frame asynchronization state occurs, it can be quickly detected. Thus, the computer can quickly start searching for synchronization words at earlier stage synchronization word detection step S15.

It is preferable that the allowable value of the number of bit errors at the earlier stage frame asynchronization detection step S20 be greater than the allowable value of the number of bit errors at the later stage frame asynchronization detection step S18. In this case, at receiver's frame synchronization indication output step S21, the computer may cause the frame asynchronization state to occur when either the earlier stage frame asynchronization detection signal or the later stage frame asynchronization detection signal is input, or it may cause the frame asynchronization state to occur only based on the earlier stage frame asynchronization detection signal.

For example, it is assumed that the number of frame synchronization detection protection stages is 2; the number of bit errors that is allowable in synchronization words when the frame asynchronization state is detected in the earlier stage is 5; the number of bit errors that is allowable in synchronization words when the frame asynchronization state is detected in the later stage is 1; the number of earlier stage frame asynchronization detection protection stages is equal to the number of later stage frame asynchronization detection protection stages and is 7. It should be noted that these values are examples and therefore the present invention is not limited to these values. These settings allow the frame asynchronization state to be more quickly detected at earlier stage frame asynchronization detection step S20 than at later stage frame asynchronization detection step S18. Also the likelihood in which it is determined that a frame asynchronization state has occurred with a small number of bit errors at the earlier stage frame asynchronization detection step S20 will decrease.

It is preferable that the predetermined number of the successive number of synchronization words that have bit errors in excess of the allowable value at the later stage frame asynchronization detection step S18 be smaller than the predetermined number of the successive number of synchronization words that have bit errors in excess of the allowable value at earlier stage frame asynchronization detection step S20. In this case, at receiver's frame synchronization indication output step S21, the computer may cause the frame asynchronization state to occur when either the earlier stage frame asynchronization detection signal or the later stage frame asynchronization detection signal is output, or it may cause the frame asynchronization state to occur only based on the later stage frame asynchronization detection signal.

For example, it is assumed that the number of frame synchronization detection protection stages is 2; the number of bit errors that is allowable in synchronization words when the frame asynchronization state is detected in the earlier stage is 1; the number of bit errors that is allowable in synchronization words when the frame asynchronization state is detected in the later stage is 1; the number of earlier stage frame asynchronization detection protection stages is 7; and the number of later stage frame asynchronization detection protection stages is 2. It should be noted that these values are examples and therefore the present invention is not limited to these values.

These settings allow the frame asynchronization state to be more quickly detected at the later stage frame asynchronization detection step S18 than at the earlier stage frame asynchronization detection step S20. Thus, at the earlier stage synchronization word detection step S15, the computer can quickly start searching for synchronization words. Also the likelihood in which the computer determines that the frame asynchronization state has occurred with a small number of bit errors at the earlier stage frame asynchronization detection step S20 will decrease.

The computer reads and executes a program recorded on a record medium such as a readable CD-ROM (Compact Disk Read Only Memory). The record medium is not limited to a CD-ROM, but it may be another medium as needed.

(Supplementary 1)

An optical transmission and reception system, comprising:

an optical transmission device including:

a frame generation circuit that adds synchronization words to an input data signal so as to generate a framed electric signal,

an FEC (Forward Error Correction) encoder that adds error correction code to said framed electric signal supplied from said frame generation circuit so as to generate an error-correction-coded electric signal, and

an electro-optical conversion circuit that converts said error-correction-coded electric signal supplied from said FEC encoder into an optical signal and transmits the optical signal; and

an optical reception device including:

an opto-electric conversion circuit that accepts said optical signal from said electro-optical conversion circuit, converts the accepted optical signal into an electric signal, and reproduces said error-correction-coded electric signal,

an earlier stage synchronization word detection circuit that detects said synchronization words from said error-correction-coded electric signal supplied from said opto-electric conversion circuit and outputs a frame-synchronized error-correction-coded electric signal,

an earlier stage frame synchronization detection circuit that counts the successive number of said synchronization words in which no bit errors have been detected by said earlier stage synchronization word detection circuit, determines that a frame synchronization establishment state has occurred when the successive number reaches a predetermined number, and outputs a frame synchronization detection signal,

an FEC decoder that corrects errors of said frame-synchronized error-correction-coded electric signal including said synchronization words supplied from said earlier stage synchronization word detection circuit and reproduces said framed electric signal,

a later stage frame asynchronization detection circuit that counts the successive number of synchronization words that have bit errors in excess of an allowable value of said synchronization words contained in said framed electric signal supplied from said FEC decoder, determines that a frame asynchronization state has occurred when the successive number reaches a predetermined number, and outputs a later stage frame asynchronization detection signal,

a receiver's frame synchronization indication output circuit that outputs a receiver's frame synchronization indication signal that causes the frame synchronization establishment state to occur based on said frame synchronization detection signal supplied from said earlier stage frame synchronization detection circuit and that causes the frame asynchronization state to occur based on said later stage frame asynchronization detection signal supplied from said later stage frame asynchronization detection circuit, and

a frame termination circuit that removes said synchronization words from said framed electric signal supplied from said FEC decoder and reproduces said data signal.

(Supplementary 2)

The optical transmission and reception system as set forth in supplementary 1,

wherein said optical reception device further includes:

an earlier stage frame asynchronization detection circuit that counts the successive number of synchronization words that have bit errors in excess of the allowable value of said synchronization words detected by said earlier stage synchronization word detection circuit, determines that the frame asynchronization state has occurred when the successive number reaches the predetermined number, and outputs an earlier stage frame asynchronization detection signal, and

wherein said receiver's frame synchronization indication output circuit outputs said receiver's frame synchronization indication signal that causes the frame synchronization establishment state to occur based on said frame synchronization detection signal supplied from said earlier stage frame synchronization detection circuit and that causes the frame asynchronization state to occur based on said earlier stage frame asynchronization detection signal supplied from said earlier stage frame asynchronization detection circuit or based on said later stage frame asynchronization detection signal supplied from said later stage frame asynchronization detection circuit.

(Supplementary 3)

The optical transmission and reception system as set forth in supplementary 2,

wherein said receiver's frame synchronization indication output circuit causes said frame asynchronization state to occur when either said earlier stage frame asynchronization detection signal or said later stage frame asynchronization detection signal is input to said receiver's frame synchronization indication output circuit.

(Supplementary 4)

The optical transmission and reception system as set forth in supplementary 2,

wherein said receiver's frame synchronization indication output circuit causes said frame asynchronization state to occur only based on said later stage frame asynchronization detection signal.

(Supplementary 5)

The optical transmission and reception system as set forth in supplementary 2,

wherein the allowable value of bit errors detected by said earlier stage frame asynchronization detection circuit is greater than the allowable value of bit errors detected by said later stage frame asynchronization detection circuit, and

wherein said receiver's frame synchronization indication output circuit causes said frame asynchronization state to occur when either said earlier stage frame asynchronization detection signal or said later stage frame asynchronization detection signal is input to said receiver's frame synchronization indication output circuit.

(Supplementary 6)

The optical transmission and reception system as set forth in supplementary 2,

wherein the allowable value of bit errors detected by said earlier stage frame asynchronization detection circuit is greater than the allowable value of bit errors detected by said later stage frame asynchronization detection circuit, and

wherein said receiver's frame synchronization indication output circuit causes said frame asynchronization state to occur only based on said earlier stage frame asynchronization detection signal.

(Supplementary 7)

The optical transmission and reception system as set forth in supplementary 2,

wherein the predetei mined number of the successive number of synchronization words that have bit errors in excess of the allowable value with respect to said later stage frame asynchronization detection circuit is smaller than the predetermined number of the successive number of synchronization words that have bit errors in excess of the allowable value with respect to said earlier stage frame asynchronization detection circuit, and

wherein said receiver's frame synchronization indication output circuit causes said frame asynchronization state to occur when either said earlier stage frame asynchronization detection signal or said later stage frame asynchronization detection signal is input to said receiver's frame synchronization indication output circuit.

(Supplementary 8)

The optical transmission and reception system as set forth in supplementary 2,

wherein the predetermined number of the successive number of synchronization words that have bit errors in excess of the allowable value with respect to said later stage frame asynchronization detection circuit is smaller than the predetermined number of the successive number of synchronization words that have bit errors in excess of the allowable value with respect to said earlier stage frame asynchronization detection circuit, and

wherein said receiver's frame synchronization indication output circuit causes said frame asynchronization state to occur only based on said later stage frame asynchronization detection signal.

(Supplementary 9)

An optical transmission and reception method, comprising:

adding synchronization words to an input data signal so as to generate a framed electric signal;

adding error correction code to said framed electric signal so as to generate error-correction-coded electric signal;

converting said error-correction-coded electric signal into an optical signal and transmitting the optical signal;

receiving said optical signal, converting the received optical signal into an electric signal, and reproducing said error-correction-coded electric signal;

detecting said synchronization words from said error-correction-coded electric signal and outputting a frame-synchronized error-correction-coded electric signal;

counting the successive number of synchronization words that do not have bit errors of said synchronization words detected in said error-correction-coded electric signal, determining that a frame synchronization establishment state has occurred when the successive number reaches a predetermined number, and outputting a frame asynchronization detection signal;

correcting errors of said frame-synchronized error-correction-coded electric signal including said synchronization words and reproducing said framed electric signal;

counting the successive number of synchronization words that have bit errors in excess of an allowable value of said synchronization words contained in said framed electric signal, determining that a frame asynchronization state has occurred when the successive number reaches a predeteimined number, and outputting a later stage frame asynchronization detection signal; and

outputting a receiver's frame synchronization indication signal that causes the frame asynchronization state to occur based on said later stage frame asynchronization detection signal.

(Supplementary 10)

The optical transmission and reception method as set forth in supplementary 9, further comprising:

counting the successive number of synchronization words that have bit errors in excess of the allowable value of said synchronization words detected by said earlier stage synchronization word detection circuit, determining that a frame asynchronization state has occurred when the successive number reaches the predetermined number, and outputting said frame asynchronization detection signal, and

wherein said outputting said receiver's frame synchronization indication signal includes outputting said receiver's frame synchronization indication signal based on said earlier stage frame asynchronization detection signal or said later stage frame asynchronization detection signal.

(Supplementary 11)

The optical transmission and reception method as set forth in supplementary 10,

wherein said outputting said receiver's frame synchronization indication signal includes causing said frame asynchronization state to occur when either said earlier stage frame asynchronization detection signal or said later stage frame asynchronization detection signal is input.

(Supplementary 12)

The optical transmission and reception method as set forth in supplementary 10,

wherein said outputting said receiver's frame synchronization indication signal includes causing said frame asynchronization state to occur only based on said later stage frame asynchronization detection signal.

(Supplementary 13)

The optical transmission and reception method as set forth in supplementary 10,

wherein said allowable value based on which said earlier stage frame asynchronization detection signal is output is greater than said allowable value based on which said later stage frame asynchronization detection signal is output,

wherein said outputting said receiver's frame synchronization indication signal includes causing said frame asynchronization state to occur when either said earlier stage frame asynchronization detection signal or said later stage frame asynchronization detection signal is input.

(Supplementary 14)

The optical transmission and reception method as set forth in supplementary 10,

wherein said allowable value based on which said earlier stage frame asynchronization detection signal is output is greater than said allowable value based on which said later stage frame asynchronization detection signal is output,

wherein said outputting said receiver's frame synchronization indication signal includes causing said frame asynchronization state to occur only based on said earlier stage frame asynchronization detection signal.

(Supplementary 15)

The optical transmission and reception method as set forth in supplementary 10,

wherein the predetermined number of the successive number of synchronization words that have bit errors in excess of said allowable value based on which said later stage frame asynchronization detection signal output is smaller than the predetermined number of the successive number of synchronization words that have bit errors in excess of said allowable value based on which said earlier stage frame asynchronization detection signal is output, and

wherein said outputting said receiver's frame synchronization indication signal includes causing said frame asynchronization state to occur when either said earlier stage frame asynchronization detection signal or said later stage frame asynchronization detection signal is input.

(Supplementary 16)

The optical transmission and reception method as set forth in supplementary 10,

wherein the predetermined number of the successive number of synchronization words that have bit errors in excess of said allowable value based on which said later stage frame asynchronization detection signal is output is smaller than the predetermined number of the successive number of synchronization words that have bit errors in excess of said allowable value based on which said earlier stage frame asynchronization detection signal is output, and

wherein said outputting said receiver's frame synchronization indication signal includes causing said frame asynchronization state to occur only based on said later stage frame asynchronization detection signal.

(Supplementary 17)

An optical reception device, comprising:

an opto-electric conversion circuit that accepts an optical signal and converts the accepted optical signal into an electric signal so as to reproduce an error-correction-coded electric signal;

an earlier stage synchronization word detection circuit that detects synchronization words in said error-correction-coded electric signal supplied from said opto-electric conversion circuit and outputs a frame-synchronized error-correction-coded electric signal;

an earlier stage frame synchronization detection circuit that counts the successive number of said synchronization words in which no bit errors have been detected by said earlier stage synchronization word detection circuit, determines that a frame synchronization establishment state has occurred when the successive number reaches a predetermined number, and outputs a frame synchronization detection signal;

an FEC decoder that corrects errors of said frame-synchronized error-correction-coded electric signal including said synchronization words supplied from said earlier stage synchronization word detection circuit;

a later stage frame asynchronization detection circuit that counts the successive number of synchronization words that have bit errors in excess of an allowable value of said synchronization words contained in said framed electric signal supplied from said FEC decoder, determines that a frame asynchronization state has occurred when the successive number reaches a predetermined number, and outputs a later stage frame asynchronization detection signal;

a receiver's frame synchronization indication output circuit that outputs a receiver's frame synchronization indication signal that causes the frame synchronization establishment state to occur based on said frame synchronization detection signal supplied from said earlier stage frame synchronization detection circuit and that causes the frame asynchronization state to occur based on said later stage frame asynchronization detection signal supplied from said later stage frame asynchronization detection circuit; and

a frame termination circuit that removes said synchronization words from said framed electric signal supplied from said FEC decoder and reproduces said data signal.

(Supplementary 18)

The optical reception device as set forth in supplementary 17, further comprising:

an earlier stage frame asynchronization detection circuit that counts the successive number of synchronization words that have bit errors in excess of the allowable value of said synchronization words detected by said earlier stage synchronization word detection circuit, determines that the frame asynchronization state has occurred when the successive number reaches the predetermined number, and outputs an earlier stage frame asynchronization detection signal,

wherein said receiver's frame synchronization indication output circuit outputs said receiver's frame synchronization indication signal that causes the frame synchronization establishment state to occur based on said frame synchronization detection signal supplied from said earlier stage frame synchronization detection circuit and that causes the frame asynchronization state to occur based on said earlier stage frame asynchronization detection signal supplied from said earlier stage frame asynchronization detection circuit or based on said later stage frame asynchronization detection signal supplied from said later stage frame asynchronization detection circuit.

(Supplementary 19)

The optical reception device as set forth in supplementary 18,

wherein said receiver's frame synchronization indication output circuit causes said frame asynchronization state to occur when either said earlier stage frame asynchronization detection signal or said later stage frame asynchronization detection signal is input to said receiver's frame synchronization indication output circuit.

(Supplementary 20)

The optical reception device as set forth in supplementary 18,

wherein said receiver's frame synchronization indication output circuit causes said frame asynchronization state to occur only based on said later stage frame asynchronization detection signal.

(Supplementary 21)

The optical reception device as set forth in supplementary 18,

wherein the allowable value of bit errors detected by said earlier stage frame asynchronization detection circuit is greater than the allowable value of bit errors detected by said later stage frame asynchronization detection circuit, and

wherein said receiver's frame synchronization indication output circuit causes said frame asynchronization state to occur when either said earlier stage frame asynchronization detection signal or said later stage frame asynchronization detection signal is input to said receiver's frame synchronization indication output circuit.

(Supplementary 22)

The optical reception device as set forth in supplementary 18,

wherein the allowable value of bit errors detected by said earlier stage frame asynchronization detection circuit is greater than the allowable value of bit errors detected by said later stage frame asynchronization detection circuit, and

wherein said receiver's frame synchronization indication output circuit causes said frame asynchronization state to occur only based on said earlier stage frame asynchronization detection signal.

(Supplementary 23)

The optical reception device as set forth in supplementary 18,

wherein the predetermined number of the successive number of synchronization words that have bit errors in excess of the allowable value with respect to said later stage frame asynchronization detection circuit is smaller than the predetermined number of the successive number of synchronization words that have bit errors in excess of the allowable value with respect to said earlier stage frame asynchronization detection circuit, and

wherein said receiver's frame synchronization indication output circuit causes said frame asynchronization state to occur when either said earlier stage frame asynchronization detection signal or said later stage frame asynchronization detection signal is input to said receiver's frame synchronization indication output circuit.

(Supplementary 24)

The optical reception device as set forth in supplementary 18,

wherein the predetermined number of the successive number of synchronization words that have bit errors in excess of the allowable value with respect to said later stage frame asynchronization detection circuit is smaller than the predetermined number of the successive number of synchronization words that have bit errors in excess of the allowable value with respect to said earlier stage frame asynchronization detection circuit, and

wherein said receiver's frame synchronization indication output circuit causes said frame asynchronization state to occur only based on said later stage frame asynchronization detection signal.

(Supplementary 25)

An optical reception method, comprising:

receiving an optical signal and converting the received optical signal into an electric signal so as to reproduce an error-correction-coded electric signal;

detecting said synchronization words from said error-correction-coded electric signal so as to output a frame-synchronized error-correction-coded electric signal;

counting the successive number of said synchronization words in which no bit errors have been detected in said error correction coded electrical signal,

determining that a frame synchronization establishment state has occurred when the successive number reaches a predetermined number, and outputting a frame synchronization detection signal;

correcting errors of said frame-synchronized error-correction-coded electric signal including said synchronization words and reproducing said framed electric signal;

counting the successive number of synchronization words that have bit errors in excess of an allowable value of said synchronization words contained in said framed electric signal, determining that a frame asynchronization state has occurred when the successive number reaches a predetermined number, and outputting a later stage frame asynchronization detection signal; and

outputting a receiver's frame synchronization indication signal that causes the frame asynchronization state to occur based on said later stage frame asynchronization detection signal.

(Supplementary 26)

The optical reception method as set forth in supplementary 25,

wherein said outputting said frame synchronization detection signal includes counting the successive number of said synchronization words that do not have bit errors, determining that the frame synchronization establishment state has occurred when the successive number reaches the predetermined number, and outputting said frame synchronization detection signal, and

wherein said outputting said receiver's frame synchronization indication signal is performed by outputting said receiver's frame synchronization indication signal based on said earlier stage frame asynchronization detection signal or said later stage frame asynchronization detection signal.

(Supplementary 27)

The optical reception method as set forth in supplementary 26,

wherein said outputting said receiver's frame synchronization indication signal includes causing said frame asynchronization state to occur when either said earlier stage frame asynchronization detection signal or said later stage frame asynchronization detection signal is input.

(Supplementary 28)

The optical reception method as set forth in supplementary 26,

wherein said outputting said receiver's frame synchronization indication signal includes causing said frame asynchronization state to occur only based on said later stage frame asynchronization detection signal.

(Supplementary 29)

The optical reception method as set forth in supplementary 26,

wherein said allowable value based on which said earlier stage frame asynchronization detection signal is output is greater than said allowable value based on which said later stage frame asynchronization detection signal is output,

wherein said outputting said receiver's frame synchronization indication signal includes causing said frame asynchronization state to occur when either said earlier stage frame asynchronization detection signal or said later stage frame asynchronization detection signal is input.

(Supplementary 30)

The optical reception method as set forth in supplementary 26,

wherein said allowable value based on which said earlier stage frame asynchronization detection signal is output is greater than said allowable value based on which said later stage frame asynchronization detection signal is output,

wherein said outputting said receiver's frame synchronization indication signal includes causing said frame asynchronization state to occur only based on said earlier stage frame asynchronization detection signal.

(Supplementary 31)

The optical reception method as set forth in supplementary 26,

wherein the predetermined number of the successive number of synchronization words that have bit errors in excess of said allowable value based on which said later stage frame asynchronization detection signal is output is smaller than the predetermined number of the successive number of synchronization words that have bit errors in excess of said allowable value based on which said earlier stage frame asynchronization detection signal is output, and

wherein said outputting said receiver's frame synchronization indication signal includes causing said frame asynchronization state to occur when either said earlier stage frame asynchronization detection signal or said later stage frame asynchronization detection signal is input.

(Supplementary 32)

The optical reception method as set forth in supplementary 26,

wherein the predetermined number of the successive number of synchronization words that have bit errors in excess of said allowable value based on which said later stage frame asynchronization detection signal is output is smaller than the predetermined number of the successive number of synchronization words that have bit errors in excess of said allowable value based on which said earlier stage frame asynchronization detection signal is output, and

wherein said outputting said receiver's frame synchronization indication signal includes causing said frame asynchronization state to occur only based on said later stage frame asynchronization detection signal.

(Supplementary 33)

A computer readable record medium that records a program that causes a computer to execute procedures, comprising:

an opto-electric conversion procedure that accepts an optical signal and converts the accepted optical signal into an electric signal so as to reproduce an error-correction-coded electric signal;

an earlier stage synchronization word detection procedure that detects said synchronization words from said error-correction-coded electric signal and outputs a frame-synchronized error-correction-coded electric signal, said earlier stage synchronization word detection procedure being preceded by said opto-electric conversion procedure;

an earlier stage frame synchronization detection procedure that counts the successive number of said synchronization words in which no bit errors have been detected by said earlier stage synchronization word detection procedure, determines that a frame synchronization establishment state has occurred when the successive number reaches a predetermined number, and outputs a frame synchronization detection signal, said earlier stage frame synchronization detection procedure being preceded by said earlier stage synchronization word detection procedure;

an FEC decode procedure that corrects errors of said frame-synchronized error-correction-coded electric signal including said synchronization words and reproduces said framed electric signal, said FEC decode procedure being preceded by said earlier stage frame synchronization detection procedure;

a later stage frame asynchronization detection procedure that counts the successive number of synchronization words that have bit errors in excess of an allowable value of said synchronization words contained in said framed electric signal, determines that a frame asynchronization state has occurred when the successive number reaches a predetermined number, and outputs a later stage frame asynchronization detection signal, said later stage frame asynchronization detection procedure being preceded by said FEC decode procedure; and

a receiver's frame synchronization indication output procedure that outputs a receiver's frame synchronization indication signal that causes the frame asynchronization state to occur based on said later stage frame asynchronization detection signal that is output at said later stage frame asynchronization detection procedure.

(Supplementary 34)

The record medium as set forth in supplementary 33,

wherein the procedures further comprise:

an earlier stage frame synchronization detection procedure that counts the successive number of said synchronization words in which no bit errors have been detected by said earlier stage synchronization word detection procedure, determines that the frame synchronization establishment state has occurred when the successive number reaches the predetermined number, and outputs a frame synchronization detection signal, said earlier stage frame synchronization detection procedure being preceded by said earlier stage synchronization word detection procedure, and

wherein said receiver's frame synchronization indication output procedure outputs the receiver's frame synchronization indication signal that causes the frame asynchronization state to occur based on said earlier stage frame asynchronization detection signal that is output at said earlier stage frame asynchronization detection procedure or based on said later stage frame asynchronization detection signal that is output at said later stage frame asynchronization detection procedure.

(Supplementary 35)

The record medium as set forth in supplementary 34,

wherein said receiver's frame synchronization indication output procedure causes said frame asynchronization state to occur when either said earlier stage frame asynchronization detection signal or said later stage frame asynchronization detection signal is input.

(Supplementary 36)

The record medium as set forth in supplementary 34,

wherein said receiver's frame synchronization indication output procedure causes said frame asynchronization state to occur only based on said later stage frame asynchronization detection signal.

(Supplementary 37)

The record medium as set forth in supplementary 34,

wherein the allowable value of bit errors detected at said earlier stage frame asynchronization detection procedure is greater than the allowable value of bit errors detected by said later stage frame asynchronization detection procedure, and

wherein said receiver's frame synchronization indication output procedure causes said frame asynchronization state to occur when either said earlier stage frame asynchronization detection signal or said later stage frame asynchronization detection signal is input.

(Supplementary 38)

The record medium as set forth in supplementary 34,

wherein the allowable value of bit errors detected at said earlier stage frame asynchronization detection procedure is greater than the allowable value of bit errors detected by said later stage frame asynchronization detection procedure, and

wherein said receiver's frame synchronization indication output procedure causes said frame asynchronization state to occur only based on said earlier stage frame asynchronization detection signal.

(Supplementary 39)

The record medium as set forth in supplementary 34,

wherein the predetermined number of the successive number of synchronization words that have bit errors in excess of the allowable value with respect to said later stage frame asynchronization detection procedure is smaller than the predetermined number of the successive number of synchronization words that have bit errors in excess of the allowable value with respect to said earlier stage frame asynchronization detection procedure, and

wherein said receiver's frame synchronization indication output procedure causes said frame asynchronization state to occur when either said earlier stage frame asynchronization detection signal or said later stage frame asynchronization detection signal is input.

(Supplementary 40)

The record medium as set forth in supplementary 34,

wherein the predetermined number of the successive number of synchronization words that have bit errors in excess of the allowable value with respect to said later stage frame asynchronization detection procedure is smaller than the predetermined number of the successive number of synchronization words that have bit errors in excess of the allowable value with respect to said earlier stage frame asynchronization detection procedure, and

wherein said receiver's frame synchronization indication output procedure causes said frame asynchronization state to occur only based on said later stage frame asynchronization detection signal.

1. An optical transmission and reception system, comprising:
an optical transmission device including:
a frame generation circuit that adds synchronization words to an input data signal so as to generate a framed electric signal,
an FEC (Forward Error Correction) encoder that adds error correction code to said framed electric signal supplied from said frame generation circuit so as to generate an error-correction-coded electric signal, and
an electro-optical conversion circuit that converts said error-correction-coded electric signal supplied from said FEC encoder into an optical signal and transmits the optical signal; and
an optical reception device including:
an opto-electric conversion circuit that accepts said optical signal from said electro-optical conversion circuit, converts the accepted optical signal into an electric signal, and reproduces said error-correction-coded electric signal,
an earlier stage synchronization word detection circuit that detects said synchronization words from said error-correction-coded electric signal supplied from said opto-electric conversion circuit and outputs a frame-synchronized error-correction-coded electric signal,
an earlier stage frame synchronization detection circuit that counts the successive number of said synchronization words in which no bit errors have been detected by said earlier stage synchronization word detection circuit, determines that a frame synchronization establishment state has occurred when the successive number reaches a predetermined number, and outputs a frame synchronization detection signal,
an FEC decoder that corrects errors of said frame-synchronized error-correction-coded electric signal including said synchronization words supplied from said earlier stage synchronization word detection circuit and reproduces said framed electric signal,
a later stage frame asynchronization detection circuit that counts the successive number of synchronization words that have bit errors in excess of an allowable value of said synchronization words contained in said framed electric signal supplied from said FEC decoder, determines that a frame asynchronization state has occurred when the successive number reaches a predetermined number, and outputs a later stage frame asynchronization detection signal,
a receiver's frame synchronization indication output circuit that outputs a receiver's frame synchronization indication signal that causes the frame synchronization establishment state to occur based on said frame synchronization detection signal supplied from said earlier stage frame synchronization detection circuit and that causes the frame asynchronization state to occur based on said later stage frame asynchronization detection signal supplied from said later stage frame asynchronization detection circuit, and
a frame termination circuit that removes said synchronization words from said framed electric signal supplied from said FEC decoder and reproduces said data signal.

2. The optical transmission and reception system as set forth in claim 1,
wherein said optical reception device further includes:
an earlier stage frame asynchronization detection circuit that counts the successive number of synchronization words that have bit errors in excess of the allowable value of said synchronization words detected by said earlier stage synchronization word detection circuit, determines that the frame asynchronization state has occurred when the successive number reaches the predetermined number, and outputs an earlier stage frame asynchronization detection signal, and
wherein said receiver's frame synchronization indication output circuit outputs said receiver's frame synchronization indication signal that causes the frame synchronization establishment state to occur based on said frame synchronization detection signal supplied from said earlier stage frame synchronization detection circuit and that causes the frame asynchronization state to occur based on said earlier stage frame asynchronization detection signal supplied from said earlier stage frame asynchronization detection circuit or based on said later stage frame asynchronization detection signal supplied from said later stage frame asynchronization detection circuit.

3. The optical transmission and reception system as set forth in claim 2,
wherein said receiver's frame synchronization indication output circuit causes said frame asynchronization state to occur when either said earlier stage frame asynchronization detection signal or said later stage frame asynchronization detection signal is input to said receiver's frame synchronization indication output circuit.

4. The optical transmission and reception system as set forth in claim 2,
wherein said receiver's frame synchronization indication output circuit causes said frame asynchronization state to occur only based on said later stage frame asynchronization detection signal.

5. The optical transmission and reception system as set forth in claim 2,
wherein the allowable value of bit errors detected by said earlier stage frame asynchronization detection circuit is greater than the allowable value of bit errors detected by said later stage frame asynchronization detection circuit, and
wherein said receiver's frame synchronization indication output circuit causes said frame asynchronization state to occur when either said earlier stage frame asynchronization detection signal or said later stage frame asynchronization detection signal is input to said receiver's frame synchronization indication output circuit.

6. The optical transmission and reception system as set forth in claim 2,
wherein the allowable value of bit errors detected by said earlier stage frame asynchronization detection circuit is greater than the allowable value of bit errors detected by said later stage frame asynchronization detection circuit, and
wherein said receiver's frame synchronization indication output circuit causes said frame asynchronization state to occur only based on said earlier stage frame asynchronization detection signal.

7. An optical transmission and reception method, comprising:
adding synchronization words to an input data signal so as to generate a framed electric signal;
adding error correction code to said framed electric signal so as to generate error-correction-coded electric signal;
converting said error-correction-coded electric signal into an optical signal and transmitting the optical signal;
receiving said optical signal, converting the received optical signal into an electric signal, and reproducing said error-correction-coded electric signal;
detecting said synchronization words from said error-correction-coded electric signal and outputting a frame-synchronized error-correction-coded electric signal;
counting the successive number of synchronization words that do not have bit errors of said synchronization words detected from said error-correction-coded electric signal, determining that a frame synchronization establishment state has occurred when the successive number reaches a predetermined number, and outputting a frame asynchronization detection signal;
correcting errors of said frame-synchronized error-correction-coded electric signal including said synchronization words and reproducing said framed electric signal;
counting the successive number of said synchronization words that do not have bit errors in said error-correction-coded electric signal, determining that a frame asynchronization state has occurred when the successive number reaches a predetermined number, and outputting a later stage frame asynchronization detection signal; and
outputting a receiver's frame synchronization indication signal that causes the frame asynchronization state to occur based on said later stage frame asynchronization detection signal.

8. An optical reception device, comprising:
an opto-electric conversion circuit that accepts an optical signal and converts the accepted optical signal into an electric signal so as to reproduce an error-correction-coded electric signal;
an earlier stage synchronization word detection circuit that detects synchronization words in said error-correction-coded electric signal supplied from said opto-electric conversion circuit and outputs a frame-synchronized error-correction-coded electric signal;
an earlier stage frame synchronization detection circuit that counts the successive number of said synchronization words in which no bit errors have been detected by said earlier stage synchronization word detection circuit, determines that a frame synchronization establishment state has occurred when the successive number reaches a predetermined number, and outputs a frame synchronization detection signal;
an FEC decoder that corrects errors of said frame-synchronized error-correction-coded electric signal including said synchronization words supplied from said earlier stage synchronization word detection circuit;
a later stage frame asynchronization detection circuit that counts the successive number of synchronization words that have bit errors in excess of an allowable value of said synchronization words contained in said framed electric signal supplied from said FEC decoder, determines that a frame asynchronization state has occurred when the successive number reaches a predetermined number, and outputs a later stage frame asynchronization detection signal;
a receiver's frame synchronization indication output circuit that outputs a receiver's frame synchronization indication signal that causes the frame synchronization establishment state to occur based on said frame synchronization detection signal supplied from said earlier stage frame synchronization detection circuit and that causes the frame asynchronization state to occur based on said later stage frame asynchronization detection signal supplied from said later stage frame asynchronization detection circuit; and
a frame termination circuit that removes said synchronization words from said framed electric signal supplied from said FEC decoder and reproduces said data signal.

9. An optical reception method, comprising:
receiving an optical signal and converting the received optical signal into an electric signal so as to reproduce an error-correction-coded electric signal;
detecting said synchronization words from said error-correction-coded electric signal;
outputting a frame-synchronized error-correction-coded electric signal;
counting the successive number of said synchronization words that do not have bit errors in said error-correction-coded electric signal, determining that a frame synchronization establishment state has occurred when the successive number reaches a predetermined number, and outputting a frame synchronization detection signal;
correcting errors of said frame-synchronized error-correction-coded electric signal including said synchronization words and reproducing said framed electric signal;
counting the successive number of synchronization words that have bit errors in excess of an allowable value of said synchronization words contained in said framed electric signal, determining that a frame asynchronization state has occurred when the successive number reaches a predetermined number, and outputting a later stage frame asynchronization detection signal; and
outputting a receiver's frame synchronization indication signal that causes the frame asynchronization state to occur based on said later stage frame asynchronization detection signal.

10. A computer readable record medium that records a program that causes a computer to execute procedures, comprising:
an opto-electric conversion procedure that accepts an optical signal and converts the accepted optical signal into an electric signal so as to reproduce an error-correction-coded electric signal;
an earlier stage synchronization word detection procedure that detects said synchronization words from said error-correction-coded electric signal and outputs a frame-synchronized error-correction-coded electric signal;
an earlier stage frame synchronization detection procedure that counts the successive number of said synchronization words in which no bit errors have been detected by said earlier stage synchronization word detection procedure, determines that a frame synchronization establishment state has occurred when the successive number reaches a predetermined number, and outputs a frame synchronization detection signal;
an FEC decode procedure that corrects errors of said frame-synchronized error-correction-coded electric signal including said synchronization words and reproduces said framed electric signal;
a later stage frame asynchronization detection procedure that counts the successive number of synchronization words that have bit errors in excess of an allowable value of said synchronization words contained in said framed electric signal, determines that a frame asynchronization state has occurred when the successive number reaches a predetermined number, and outputs a later stage frame asynchronization detection signal; and
a receiver's frame synchronization indication output procedure that outputs a receiver's frame synchronization indication signal that causes the frame asynchronization state to occur based on said later stage frame asynchronization detection signal.
